(19) United States
(12) Patent Application Publication
(10) Pub. No.: US 2026/0101641 A1
(43) Pub. Date: Apr. 9, 2026

(54) ELECTRONIC DEVICE

(71) Applicant: Samsung Display Co., LTD., Yongin-si (KR)

(72) Inventors: SUNGEUN LEE, Yongin-si (KR); KI NYENG KANG, Yongin-si (KR); HYOENG-KI KIM, Yongin-si (KR); KEUNKYU SONG, Yongin-si (KR)

(21) Appl. No.: 19/267,522

(22) Filed: Jul. 12, 2025

(30) Foreign Application Priority Data
Oct. 8, 2024 (KR) 10-2024-0136805

(51) Int. Cl. H10K 59/122; H10K 59/123; H10K 59/124; H10K 59/80; H10K 59/88

(52) U.S. Cl. CPC H10K 59/122; H10K 59/123; H10K 59/124; H10K 59/873; H10K 59/88

(57) ABSTRACT

An electronic device includes an intervening insulating layer disposed on a substrate, a pixel unit including light-emitting elements, pixel-defining patterns each having defined therein an opening and disposed on the intervening insulating layer, and a partition wall disposed between the pixel-defining patterns next (adjacent) to each other on the intervening insulating layer. The partition wall includes first layer to third layer disposed on the intervening insulating layer, a groove, in which at least a portion of the intervening insulating layer is recessed, is defined in the intervening insulating layer in a recessed region which is defined between the pixel-defining pattern and the partition wall, and a common layer and a second electrode extend from a light-emitting region to the recessed region and contact the first layer.

This application claims priority to Korean Patent Application No. 10-2024-0136805, filed on Oct. 8, 2024, and all the benefits accruing therefrom under 35 U.S.C. § 119, the content of which in its entirety is herein incorporated by reference.

### BACKGROUND

### 1. Field

The disclosure herein relates to an electronic device, and more particularly, to an electronic device with improved display quality.

### 2. Description of the Related Art

In general, an electronic apparatus such as a smartphone, a digital camera, a laptop computer, a navigation device, and a smart television, which provides an image to a user, includes an electronic device for displaying an image. The electronic device generates an image and provides the generated image to a user through a display screen.

The electronic device includes a plurality of pixels for generating an image and a plurality of lines connected to the pixels. The pixels are driven by receiving driving signals through the lines.

A variation may occur in driving voltage transferred to each of pixels in medium- and large-sized electronic apparatuses, having a large area size, such as a tablet personal computer or a smart television, and thus a design for compensating for the variation in driving voltage is desired.

### SUMMARY

The disclosure provides an electronic device capable of providing uniform driving voltage to pixels.

An embodiment of the inventive concept provides an electronic device including a substrate including a display region including light-emitting regions and a non-light-emitting region disposed between the light-emitting regions, an intervening insulating layer disposed on the substrate, a pixel unit disposed on the substrate and including light-emitting elements each including a first electrode and a second electrode overlapping a light-emitting region of the light-emitting regions and disposed on the intervening insulating layer and a common layer disposed between the first electrode and the second electrode, pixel-defining patterns disposed on the intervening insulating layer and each defining therein an opening that corresponds to the light-emitting region and exposes at least a portion of the first electrode, and a partition wall overlapping the non-light-emitting region and disposed between the pixel-defining patterns next (adjacent) to each other on the intervening insulating layer, wherein the partition wall includes a first layer disposed on the intervening insulating layer, a second layer disposed on the first layer, and a third layer disposed on the second layer, a groove, in which at least a portion of the intervening insulating layer is recessed in a direction from an upper surface to a lower surface of the intervening insulating layer, is defined in the intervening insulating layer in a recessed region which is defined between one of the pixel defining patterns and the partition wall, and the common layer and the second electrode extend from the light-emitting region to the recessed region and contact the first layer.

In an embodiment, the groove may expose a portion of a lower surface of the first layer facing the intervening insulating layer.

In an embodiment, the common layer may contact the portion of the lower surface.

In an embodiment, the second electrode may contact a side surface of the first layer.

In an embodiment, the second electrode may contact the portion of the lower surface and expose a side surface of the first layer.

In an embodiment, the second electrode may contact the portion of the lower surface, a side surface of the first layer, and a portion, of an upper surface of the first layer, exposed from the second layer.

In an embodiment, in a cross-sectional view, the groove may have a concave shape.

In an embodiment, the electronic device may further include an inter-insulating layer disposed below the intervening insulating layer, wherein the groove may penetrate the intervening insulating layer from the upper surface to the lower surface of the intervening insulating layer and expose a portion of an upper surface of the inter-insulating layer.

In an embodiment, the common layer may contact a side surface, defining the groove, of the intervening insulating layer, the portion of the upper surface of the inter-insulating layer, and the portion of the lower surface of the first layer.

In an embodiment, the electronic device may include transistors disposed on the substrate, a first connection electrode disposed on the inter-insulating layer and connected to the transistors, and a second connection electrode disposed on the intervening insulating layer and connected to the first connection electrode through a first contact hole defined in the inter-insulating layer, wherein the first electrode may be connected to the second connection electrode through a second contact hole defined in the intervening insulating layer.

In an embodiment, the first layer and the third layer may include titanium, and the second layer may include aluminum.

In an embodiment, in a cross-sectional view, each of a width of the first layer and a width of the third layer may be greater than a width of the second layer, and each of a thickness of the first layer and a thickness of the third layer may be smaller than a thickness of the second layer.

In an embodiment, the electronic device may further include a first dummy pattern disposed on the third layer and a second dummy pattern disposed on the first dummy pattern, wherein the first dummy pattern may include the same material as that of the common layer, and the second dummy pattern may include the same material as that of the second electrode.

In an embodiment, the electronic device may further include a fourth layer disposed on the third layer and including a metal different from that of the first layer and the third layer.

In an embodiment, the first layer and the third layer may include any one of titanium and molybdenum-titanium alloy, and the second layer and the fourth layer may include any one of aluminum and copper.

In an embodiment, a side surface of the second layer may be oxidized and may not have conductivity.

In an embodiment, second electrodes disconnected with the partition wall therebetween may be connected through the partition wall.

In an embodiment, the intervening insulating layer may include any one of an inorganic material and an organic material.

In an embodiment, the electronic device may further include an encapsulation layer covering the light-emitting elements.

In an embodiment, the pixel unit may be provided in plural in the display region in a manner in which each of the pixel units may include a (1-1)-th pixel which provides first color light, a (1-2)-th pixel which provides the first color light and is spaced apart from the (1-1)-th pixel along a first direction, a second pixel which provides second color light different from the first color light and is spaced apart from the (1-1)-th pixel in a first diagonal direction, and a third pixel which provides third color light different from the first color light and the second color light, is spaced apart from the second pixel along a second direction crossing the first direction, and is spaced apart from the (1-2)-th pixel along a second diagonal direction crossing the first diagonal direction.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of an embodiment of an electronic device according to the inventive concept;

FIG. 1B is a block diagram of an embodiment of an electronic device according to the inventive concept;

FIG. 2 is a cross-sectional view of an embodiment of an electronic device according to the inventive concept;

FIG. 3 is a cross-sectional view of an embodiment of a display panel according to the inventive concept;

FIG. 4A is a block diagram of an embodiment of a display module according to the inventive concept;

FIG. 4B is an equivalent circuit of one pixel among pixels illustrated in FIG. 4A;

FIG. 5A is a plan view of an embodiment of a pixel unit according to the inventive concept;

FIG. 5B is a plan view of an embodiment of a pixel according to the inventive concept;

FIG. 6 is a cross-sectional view taken along I-I′ of FIG. 5A;

FIG. 7 is a cross-sectional view taken along II-II′ of FIG. 5A;

FIG. 8 is a cross-sectional view of an embodiment of a display panel according to the inventive concept;

FIG. 9 is a cross-sectional view of an embodiment of a display panel according to the inventive concept;

FIG. 10 is a cross-sectional view of an embodiment of a display panel according to the inventive concept; and

FIG. 11 is a cross-sectional view of an embodiment of a display panel according to the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concept. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

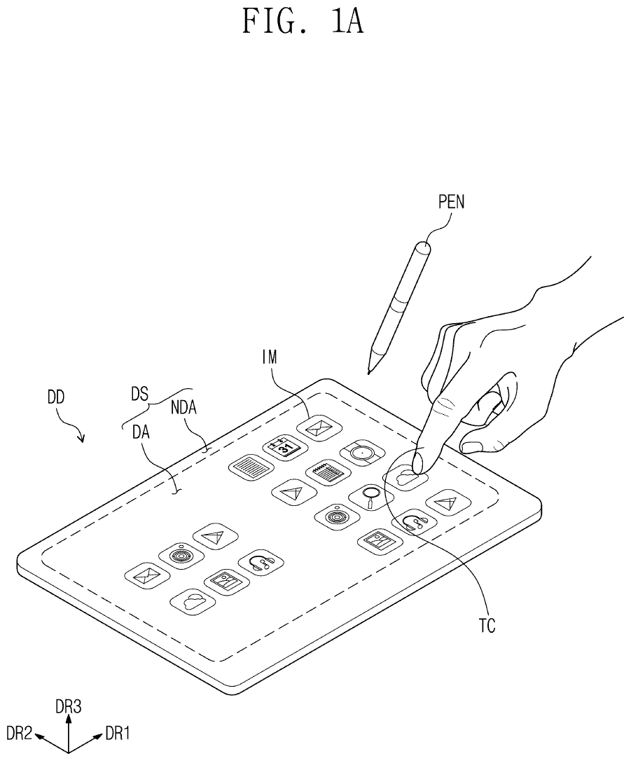

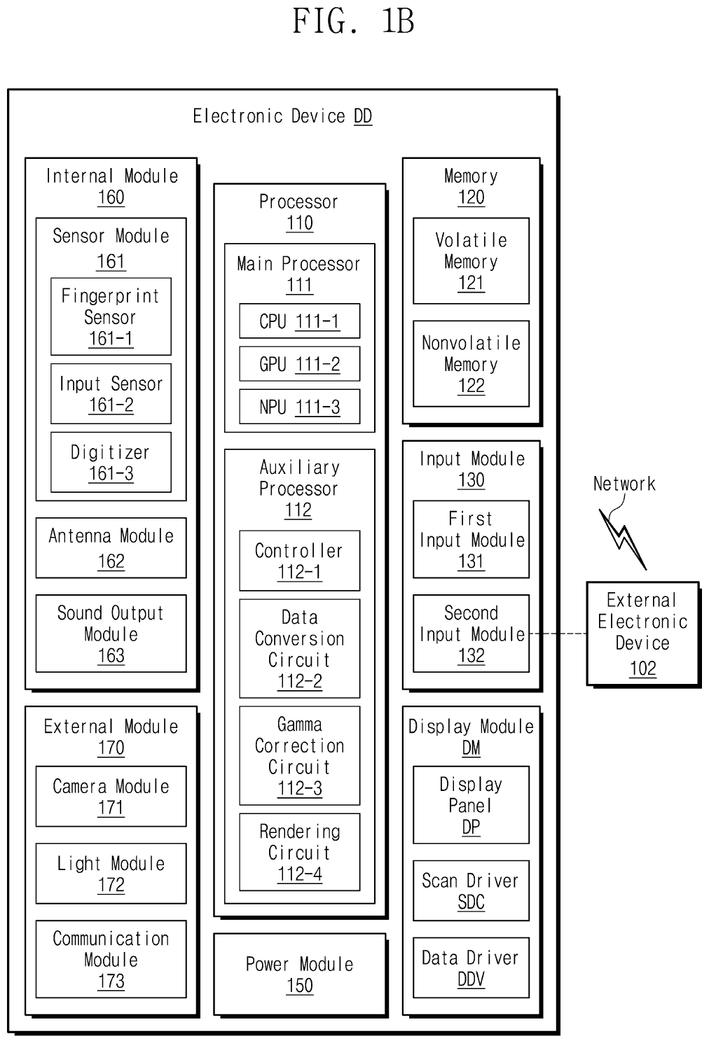

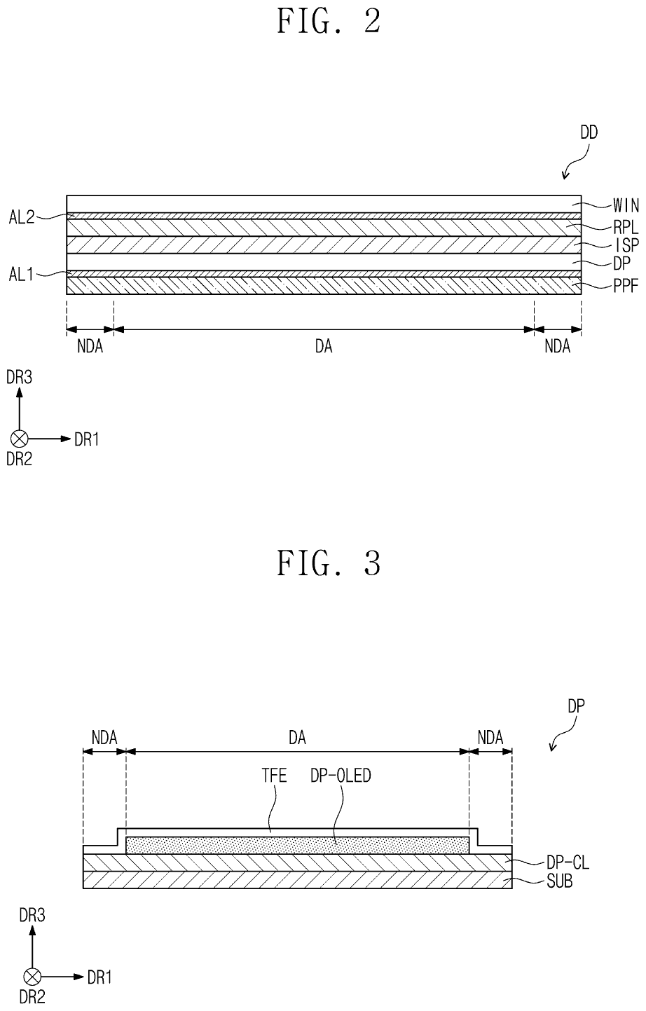

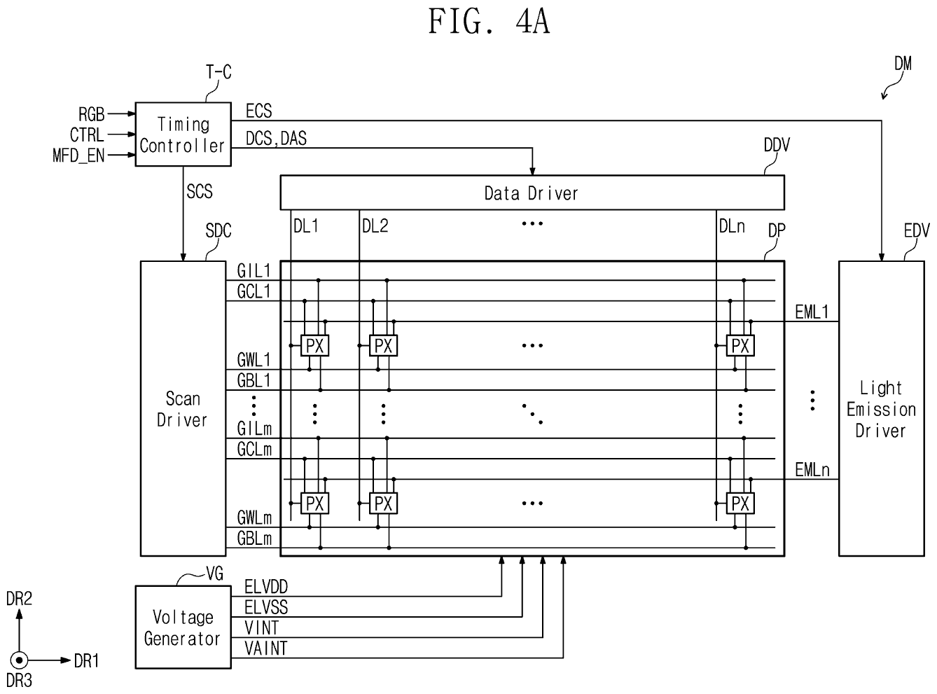

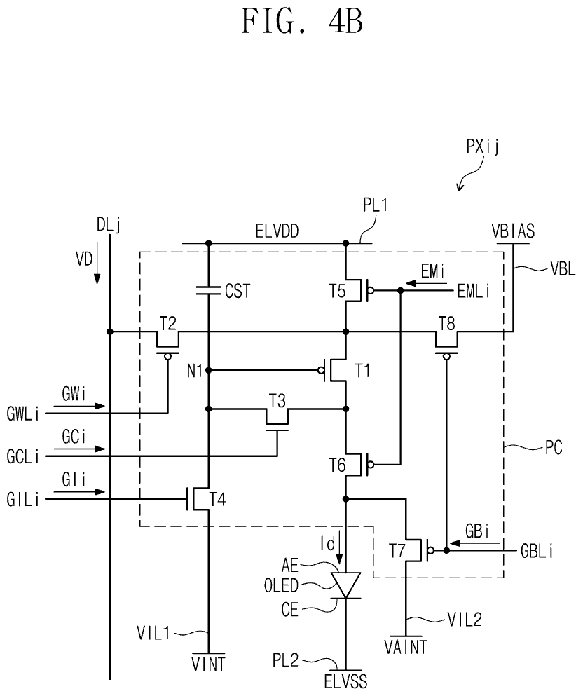

FIG. 1A is a perspective view of an embodiment of an electronic device according to the inventive concept. FIG. 1B is a block diagram of an embodiment of an electronic device according to the inventive concept. FIG. 2 is a cross-sectional view of an embodiment of an electronic device according to the inventive concept. FIG. 3 is a cross-sectional view of an embodiment of a display panel according to the inventive concept. FIG. 4A is a block diagram of an embodiment of a display module according to the inventive concept. FIG. 4B is an equivalent circuit of one pixel among pixels illustrated in FIG. 4A.

Referring to FIG. 1A, an electronic device DD in an embodiment of the inventive concept may have long sides extending in parallel in a first direction DR1 and short sides extending in parallel in a second direction DR2 crossing the first direction DR1. Corners, of the electronic device DD, connecting the long sides and the short sides may have a curved shape. The corners, of the electronic device DD, having a curved shape may be defined as round corners. A shape of such an electronic device DD may be defined as a round-cornered quadrangle. However, this is one embodiment of a shape of one electronic device DD, and a shape of the electronic device DD is not limited to a round-cornered quadrangle.

Hereinafter, a direction substantially perpendicularly crossing a plane defined by the first direction DR1 and the second direction DR2 is defined as a third direction DR3. In addition, in the specification, the wording “in a plan view” is defined as a state of being viewed in the third direction DR3.

A front surface of the electronic device DD may be defined as a display surface DS and have a plane defined by the first direction DR1 and the second direction DR2. Images IM which is generated in the electronic device DD may be provided to a user through the display surface DS.

The display surface DS may include a display region DA and a non-display region NDA around the display region DA. An image may be displayed in the display region DA, and an image may not be displayed in the non-display region NDA. The non-display region NDA may surround the display region DA and define an edge of the electronic device DD printed in a predetermined color.

The display region DA may have a round-cornered quadrangular shape according to a shape of the electronic device DD. In an embodiment, the display region DA may include sides, of a quadrangle, extending in the first direction DR1 and the second direction DR2 and rounded corners connecting the sides, for example. Among four sides, sides extending in the first direction DR1 may be defined as long sides, and sides extending in the second direction DR2 may be defined as short sides.

The electronic device DD may sense inputs applied from the outside of the electronic device DD. In an embodiment, the electronic device DD may sense a first input from a touch pen PEN and a second input from a touch TC, for example. The touch pen PEN may be defined as an input device.

The touch pen PEN may be an active pen which outputs a signal. The second input from the touch TC may include external inputs in various forms such as part of a user's body, light, heat, or pressure.

The electronic device DD and the touch pen PEN may communicate bidirectionally. The electronic device DD may provide an uplink signal to the touch pen PEN. In an embodiment, the uplink signal may include information such as panel information and protocol version, for example, but is not particularly limited thereto.

The touch pen PEN may provide a downlink signal to the electronic device DD. The downlink signal may include a synchronization signal or status information about the touch pen PEN. In an embodiment, the downlink signal may include coordinate information about the touch pen PEN, battery information about the touch pen PEN, inclination information about the touch pen PEN, a variety of information stored in the touch pen PEN, and/or the like, for example, but is not particularly limited thereto.

The electronic device DD may be used in large-sized electronic apparatuses such as a television, a monitor, or an outdoor billboard. Also, the electronic device DD may be used in medium- and small-sized electronic apparatuses such as a personal computer, a laptop computer, a personal digital terminal, a car navigation unit, a game console, a smartphone, a tablet personal computer, or a camera. However, these are merely embodiments, and the electronic device DD may also be used in other electronic apparatuses as long as the electronic device DD does not depart from the inventive concept.

FIG. 1B illustrates an embodiment of a block diagram of an electronic device DD. Referring to FIG. 1B, the electronic device DD outputs a variety of information through a display module DM in an operating system. When a processor 110 executes an application stored in a memory 120, the display module DM provides application information to a user through a display panel DP.

The processor 110 obtains an external input through an input module 130 or a sensor module 161 and executes an application corresponding to the external input. In an embodiment, when a user selects a camera icon displayed on the display panel DP, the processor 110 obtains a user input through an input sensor 161-2 and activates a camera module 171, for example. The processor 110 transmits, to the display module DM, image data corresponding to a captured image which is obtained through the camera module 171. The display module DM may display an image corresponding to the captured image through the display panel DP.

In another embodiment, when personal information authentication is executed in the display module DM, a fingerprint sensor 161-1 obtains input fingerprint information as input data. The processor 110 compares the input data obtained through the fingerprint sensor 161-1 with authentication data stored in the memory 120, and executes an application according to a comparison result. The display module DM may display information which is executed according to a logic of the application through the display panel DP.

In another embodiment, when a music streaming icon displayed on the display module DM is selected, the processor 110 obtains a user input through the input sensor 161-2 and activates a music streaming application stored in the memory 120. When a music execution command is input in the music streaming application, the processor 110 activates a sound output module 163 and provides sound information corresponding to the music execution command to a user.

An operation of the electronic device DD is briefly described above. Hereinafter, a configuration of the electronic device DD is described in detail. Some of components of the electronic device DD to be described later may be integrated and provided as one component, and one component may be separated into two or more components and provided.

Referring to FIG. 1B, the electronic device DD may communicate with an external electronic device 102 via a network (e.g., a short-range wireless communication network or a long-range wireless communication network). In an embodiment, the electronic device DD may include the processor 110, the memory 120, the input module 130, the display module DM, a power module 150, an internal module 160, and an external module 170. In an embodiment, in the electronic device DD, at least one of the components described above may be omitted, or one or more other components may be added. In an embodiment, some (e.g., the sensor module 161, an antenna module 162, or the sound output module 163) of the components described above may be integrated into another component (e.g., the display module DM).

The processor 110 may execute software to control at least one another component (e.g., hardware or software component) of the electronic device DD connected to the processor 110 and perform various data processing or operations. In an embodiment, as at least part of the data processing or operations, the processor 110 may store data or a command received from another component (e.g., the input module 130, the sensor module 161, or a communication module 173) in a volatile memory 121 and process the data or command stored in the volatile memory 121, and result data may be stored in a nonvolatile memory 122.

The processor 110 may include a main processor 111 and an auxiliary processor 112. The main processor 111 may include one or more among a central processing unit (“CPU”) 111-1 and an application processor (“AP”). The main processor 111 may further include one or more among a graphic processing unit (“GPU”) 111-2, a communication processor (“CP”), and an image signal processor (“ISP”). The main processor 111 may further include a neural processing unit (“NPU”) 111-3. A neural processing unit is a processor that is specialized for processing an artificial intelligence model, and the artificial intelligence model may be generated through machine learning. The artificial intelligence model may include a plurality of artificial neural network layers. An artificial neural network may be one of a deep neural network (“DNN”), a convolutional neural network (“CNN”), a recurrent neural network (“RNN”), a restricted boltzmann machine (“RBM”), a deep belief network (“DBN”), a bidirectional recurrent deep neural network (“BRDNN”), deep Q-networks, or a combination of two or more of the above, but is not limited to the examples described above. The artificial intelligence model may include a software structure in addition to or instead of a hardware structure. At least two among the processing units and processors described above may be implemented as one integrated component (e.g., a single chip) or may be each implemented as an independent component (e.g., a plurality of chips).

The auxiliary processor 112 may include a controller 112-1. The controller 112-1 may include an interface conversion circuit and a timing control circuit. The controller 112-1 receives an image signal from the main processor 111, converts data format of the image signal to comply with specifications of interface with the display module DM and outputs image data. The controller 112-1 may output various control signals desired for driving the display module DM.

The auxiliary processor 112 may further include a data conversion circuit 112-2, a gamma correction circuit 112-3, a rendering circuit 112-4, etc. The data conversion circuit 112-2 may receive image data from the controller 112-1, and may compensate for the image data so that an image is displayed at a desired luminance according to characteristics of the electronic device DD, a user's setting, or the like, or may convert the image data to reduce power consumption, to compensate for an afterimage, or the like. The gamma correction circuit 112-3 may convert image data, a gamma reference voltage, or the like so that an image displayed on the electronic device DD has a desired gamma characteristic. The rendering circuit 112-4 may receive image data from the controller 112-1 and render the image data in consideration of pixel arrangement of the display panel DP applied to the electronic device DD, etc. At least one of the data conversion circuit 112-2, the gamma correction circuit 112-3, or the rendering circuit 112-4 may be integrated into another component (e.g., the main processor 111 or the controller 112-1). At least one of the data conversion circuit 112-2, the gamma correction circuit 112-3, or the rendering circuit 112-4 may be integrated into a data driver DDV to be described later.

The memory 120 may store various pieces of data used by at least one component (e.g., the processor 110 or the sensor module 161) of the electronic device DD, and output data or input data about a command related thereto. The memory 120 may include at least one of the volatile memory 121 or the nonvolatile memory 122.

The input module 130 may receive data or a command to be used in a component (e.g., the processor 110, the sensor module 161, or the sound output module 163) of the electronic device DD from the outside (e.g., a user or the external electronic device 102) of the electronic device DD.

The input module 130 may include a first input module 131 to which a command or data is input from a user and a second input module 132 to which a command or data is input from the external electronic device 102. The first input module 131 may include a microphone, a mouse, a keyboard, a key (e.g., button) or a pen (e.g., passive pen or active pen). The second input module 132 may support a designated protocol for wired or wireless connection to the external electronic device 102. In an embodiment, the second input module 132 may include a high definition multimedia interface (“HDMI”), a universal serial bus (“USB”) interface, a secure digital (“SD”) card interface, or an audio interface. The second input module 132 may include a connector for physical connection to the external electronic device 102, e.g., an HDMI connector, a USB connector, an SD card connector, or an audio connector (e.g., headphone connector).

The display module DM visually provides information to a user. The display module DM may include the display panel DP, a scan driver SDC, and a data driver DDV. The display module DM may further include a chassis, a bracket, and a window for protecting the display panel DP.

The display panel DP may include a liquid crystal display panel, an organic light-emitting display panel, or an inorganic light-emitting display panel, and a type of the display panel DP is not particularly limited. The display panel DP may be a rigid-type display panel or a flexible-type display panel that is rollable or foldable. The display module DM may further include a supporter that supports the display panel DP, a bracket, a heat dissipation member, or the like.

The scan driver SDC may be disposed (e.g., mounted) on the display panel DP as a driving chip. In addition, the scan driver SDC may be integrated to the display panel DP. In an embodiment, the scan driver SDC may include an amorphous silicon TFT gate driver circuit (“ASG”), a low temperature polycrystalline silicon (“LTPS”) TFT gate driver circuit, or an oxide semiconductor TFT gate driver circuit (“OSG”) built in the display panel DP, for example. The scan driver SDC receives a control signal from the controller 112-1 and outputs scan signals to the display panel DP in response to the control signal.

The display panel DP may further include a light emission driver. The light emission driver outputs a light emission control signal to the display panel DP in response to a control signal received from the controller 112-1. The light emission driver may be formed separately from the scan driver SDC or may be integrated to the scan driver SDC.

The data driver DDV receives a control signal from the controller 112-1, converts image data into an analog voltage (e.g., data voltage) in response to the control signal, and then outputs data voltages to the display panel DP.

The data driver DDV may be integrated to another component (e.g., the controller 112-1). Functions of the timing control circuit and the interface conversion circuit of the controller 112-1 described above may be integrated to the data driver DDV.

The display module DM may further include a light emission driver, a voltage generation circuit, or the like. The voltage generation circuit may output various voltages desired for driving the display panel DP.

The power module 150 supplies power to a component of the electronic device DD. The power module 150 may include a battery which charges a power voltage. The battery may include a non-rechargeable primary cell, a rechargeable secondary cell, or a fuel cell. The power module 150 may include a power management integrated circuit (“PMIC”). The PMIC supplies optimized power to each of the module described above and a module to be described later. The power module 150 may include a wireless power transmission/reception member electrically connected to the battery. The wireless power transmission/reception member may include a plurality of antenna radiators in a coil form.

The electronic device DD may further include the internal module 160 and the external module 170. The internal module 160 may include the sensor module 161, the antenna module 162, and the sound output module 163. The external module 170 may include the camera module 171, a light module 172, and the communication module 173.

The sensor module 161 may sense an input from a user's body or an input from a pen of the first input module 131 and generate a data value or an electrical signal corresponding to the input. The sensor module 161 may include at least one of the fingerprint sensor 161-1, the input sensor 161-2, or a digitizer 161-3.

The fingerprint sensor 161-1 may generate a data value corresponding to a user's fingerprint. The fingerprint sensor 161-1 may include one of an optical fingerprint sensor or a capacitive fingerprint sensor.

The input sensor 161-2 may generate a data value corresponding to coordinate information about an input from a user's body or an input from a pen. The input sensor 161-2 generates the amount of change in capacitance due to an input as a data value. The input sensor 161-2 may sense an input from a passive pen or transmit/receive data to/from an active pen.

The input sensor 161-2 may measure a biosignal such as blood pressure, water, or body fat. In an embodiment, when a user contacts a sensor layer or a sensing panel with a part of a user's body and does not move for a certain amount of time, on the basis of a change in electric field caused by the part of the user's body, the input sensor 161-2 may sense a biosignal and output information which is desired by the user to the display module DM, for example.

The digitizer 161-3 may generate a data value corresponding to coordinate information about an input from a pen. The digitizer 161-3 generates the amount of electromagnetic change due to an input as a data value. The digitizer 161-3 may sense an input from a passive pen or transmit/receive data to/from an active pen.

At least one of the fingerprint sensor 161-1, the input sensor 161-2 or the digitizer 161-3 may be implemented as a sensor layer which is formed on the display panel DP through a continuous process. The fingerprint sensor 161-1, the input sensor 161-2, and the digitizer 161-3 may be disposed above the display panel DP, and any one of the fingerprint sensor 161-1, the input sensor 161-2 and the digitizer 161-3, e.g., the digitizer 161-3 may be disposed below the display panel DP.

At least two of the fingerprint sensor 161-1, the input sensor 161-2, and the digitizer 161-3 may be integrated to one sensing panel through the same process. In a case in which at least two of the fingerprint sensor 161-1, the input sensor 161-2, and the digitizer 161-3 are integrated to one sensing panel, the sensing panel may be disposed between the display panel DP and a window disposed above the display panel DP. In an embodiment, the sensing panel may be disposed on the window, and a position of the sensing panel is not particularly limited.

At least one of the fingerprint sensor 161-1, the input sensor 161-2 or the digitizer 161-3 may be built in the display panel DP. That is, at least one of the fingerprint sensor 161-1, the input sensor 161-2 or the digitizer 161-3 may be simultaneously formed through a process of forming elements (e.g., a light-emitting element, a transistor, etc.) included in the display panel DP.

In addition, the sensor module 161 may generate an electrical signal or a data value corresponding to an internal state or an external state of the electronic device DD. The sensor module 161 may further include a gesture sensor, a gyro sensor, a barometric pressure sensor, a magnetic sensor, an acceleration sensor, a grip sensor, a proximity sensor, a color sensor, an infrared (“IR”) sensor, a biometric sensor, a temperature sensor, a humidity sensor, or an illuminance sensor, for example.

The antenna module 162 may include one or more antennas for transmitting or receiving a signal or power to or from the outside. In an embodiment, the communication module 173 may transmit or receive a signal to or from an external electronic device through an antenna which is suitable for a communication method. An antenna pattern of the antenna module 162 may be integrated to one component (e.g., the display panel DP) of the display module DM, the input sensor 161-2, or the like.

The sound output module 163 may be a device for outputting a sound signal to the outside of the electronic device DD and include a speaker used for general purposes such as playing multimedia or playing a recording and a receiver used only for receiving a call, for example. In an embodiment, the receiver may be formed integrally with or separately from the speaker. A sound output pattern of the sound output module 163 may be integrated to the display module DM.

The camera module 171 may capture a still image and a moving image. In an embodiment, the camera module 171 may include one or more lenses, an image sensor, or an image signal processor. The camera module 171 may further include an IR camera capable of measuring presence/absence of a user, a position of a user, a gaze of a user, etc.

The light module 172 may provide light. The light module 172 may include a light-emitting diode or a xenon lamp. The light module 172 may operate in association with the camera module 171 or operate independently.

The communication module 173 may support establishing a wired or wireless communication channel between the electronic device DD and the external electronic device 102 and performing communication via the established communication channel. The communication module 173 may include any one or both of a wireless communication module such as a cellular communication module, a short-range wireless communication module, or a global navigation satellite system (“GNSS”) communication module and a wired communication module such as a local area network (“LAN”) communication module or a power line communication module. The communication module 173 may communicate with the external electronic device 102 via a short-range communication network such as Bluetooth, Wi-Fi direct, or IR data association (“IrDA”) or a long-range communication network such as a cellular network, internet, or a computer network (e.g., LAN or WAN). The various types of communication module 173 described above may be implemented as one chip or may be each implemented as a separate chip.

The input module 130, the sensor module 161, the camera module 171, etc., may be used to control an operation of the display module DM in association with the processor 110.

The processor 110 outputs a command or data to the display module DM, the sound output module 163, the camera module 171 or the light module 172 on the basis of input data received from the input module 130. In an embodiment, the processor 110 may generate image data in correspondence to input data applied through a mouse, an active pen, or the like and output the image data to the display module DM, or may generate command data in correspondence to input data and output the command data to the camera module 171 or the light module 172, for example. When input data is not received from the input module 130 for a predetermined amount of time, the processor 110 may change an operation mode of the electronic device DD to a relatively low power mode or a sleep mode, thereby reducing power consumption of the electronic device DD.

The processor 110 outputs a command or data to the display module DM, the sound output module 163, the camera module 171, or the light module 172 on the basis of sensing data received from the sensor module 161. In an embodiment, the processor 110 may compare authentication data applied by the fingerprint sensor 161-1 with authentication data stored in the memory 120, and then may execute an application according to a comparison result, for example. The processor 110 may execute a command or may output corresponding image data to the display module DM on the basis of sensing data that is sensed by the input sensor 161-2 or the digitizer 161-3. In a case in which a temperature sensor is included in the sensor module 161, the processor 110 may receive temperature data about a measured temperature from the sensor module 161 and further perform luminance correction on image data, etc., on the basis of the temperature data.

The processor 110 may receive measurement data about presence/absence of a user, a position of a user, a gaze of a user, etc., from the camera module 171. The processor 110 may further perform luminance correction on image data, etc., on the basis of the measurement data. In an embodiment, the processor 110 determines presence/absence of a user through an input from the camera module 171, and then may output image data of which luminance is corrected through the data conversion circuit 112-2 or the gamma correction circuit 112-3 to the display module DM, for example.

Some of the above components may be connected to each other through a communication method between peripheral devices, e.g., a bus, a general purpose input/output (“GPIO”), a serial peripheral interface (“SPI”), a mobile industry processor interface (“MIPI”), or an ultra path interconnect (“UPI”) link and may exchange a signal (e.g., command or data). The processor 110 may communicate with the display module DM through a mutually agreed interface, and for example, may use any one of the communication methods described above without being limited to the communication methods described above.

The electronic device DD according to various embodiments disclosed herein may be devices in various forms. The electronic device DD may include at least one of a portable communication device (e.g., smartphone), a computer device, a portable multimedia device, a portable medical device, a camera, a wearable device, or a home appliance, for example. The electronic device DD in an embodiment herein is not limited to the devices described above.

FIG. 2 is a diagram illustrating a cross section of the electronic device illustrated in FIG. 1A as an illustrative embodiment. FIG. 2 illustrates a cross section of the electronic device DD viewed in the second direction DR2 as an illustrative embodiment. In FIG. 2, some of the components of the electronic device DD described with reference to FIG. 1B are not illustrated.

Referring to FIG. 2, the electronic device DD may include a display panel DP, an input sensor ISP, an anti-reflective layer RPL, a window WIN, a panel protective film PPF, and first and second adhesive layers AL1 and AL2. The input sensor ISP illustrated in FIG. 2 may be the same component as the input sensor 161-2 described with reference to FIG. 1B.

The display panel DP in an embodiment of the inventive concept may be an emissive display panel. In an embodiment, the display panel DP may be an organic light-emitting display panel or an inorganic light-emitting display panel, for example. An emission layer of the organic light-emitting display panel may include an organic light-emitting material. An emission layer of the inorganic light-emitting display panel may include quantum dots, quantum rods, or the like. Hereinafter, the display panel DP is described as an organic light-emitting display panel.

The input sensor ISP may be disposed on the display panel DP. The input sensor ISP may include a plurality of sensing parts (not shown) for sensing an external input using a capacitive method. The input sensor ISP may be directly manufactured on the display panel DP when the electronic device DD is manufactured. Accordingly, the input sensor ISP in an embodiment may be directly disposed on the display panel DP. However, the inventive concept is not limited thereto, and the input sensor ISP may be manufactured as a panel separate from the display panel DP and may be attached to the display panel DP through an adhesive layer.

The anti-reflective layer RPL may be disposed on the input sensor ISP. The anti-reflective layer RPL may be directly manufactured on the input sensor ISP when the electronic device DD is manufactured. However, the inventive concept is not limited thereto, and the anti-reflective layer RPL may be manufactured as a separate panel and attached to the input sensor ISP through an adhesive layer.

The anti-reflective layer RPL may be defined as an external light anti-reflection film. The anti-reflective layer RPL may reduce reflectance for external light incident toward the display panel DP from above the electronic device DD. External light may not be viewed by a user due to the anti-reflective layer RPL.

When external light travelling toward the display panel DP is reflected on the display panel DP and provided back to an external user, the user may view the external light as in the case of viewing light reflected from a mirror. To prevent such a phenomenon, as one of the embodiments, the anti-reflective layer RPL may include a plurality of color filters that display the same color as pixels of the display panel DP.

The color filters may filter external light to the same color as that of the pixels. In such a case, the external light may not be viewed by a user. However, the inventive concept is not limited thereto, and the anti-reflective layer RPL may include a retarder and/or a polarizer to reduce reflectance for external light.

The window WIN may be disposed on the anti-reflective layer RPL. The window WIN may protect the display panel DP, the input sensor ISP, and the anti-reflective layer RPL from external scratches and impact.

The panel protective film PPF may be disposed below the display panel DP. The panel protective film PPF may protect a lower portion of the display panel DP. The panel protective film PPF may include a flexible plastic material such as polyethyleneterephthalate (“PET”).

The first adhesive layer AL1 may be disposed between the display panel DP and the panel protective film PPF, and the display panel DP and the panel protective film PPF may be coupled to each other by the first adhesive layer AL1. The second adhesive layer AL2 may be disposed between the window WIN and the anti-reflective layer RPL, and the window WIN and the anti-reflective layer RPL may be coupled to each other by the second adhesive layer AL2.

FIG. 3 is a diagram illustrating a cross section of the display panel illustrated in FIG. 2 as an illustrative embodiment. As one of the embodiments, FIG. 3 illustrates a cross section of the display panel DP viewed in the second direction DR2.

Referring to FIG. 3, the display panel DP may include a substrate SUB, a circuit element layer DP-CL disposed on the substrate SUB, a display element layer DP-OLED disposed on the circuit element layer DP-CL, and a thin-film encapsulation layer (also referred to as an encapsulation layer) TFE disposed on the display element layer DP-OLED.

The substrate SUB may include a display region DA and a non-display region NDA around the display region DA. The substrate SUB may include glass or a flexible plastic material such as polyimide. The display element layer DP-OLED may be disposed on the display region DA.

A plurality of pixels may be disposed in the circuit element layer DP-CL and the display element layer DP-OLED. Each of the pixels may include a transistor disposed in the circuit element layer DP-CL and a light-emitting element disposed in the display element layer DP-OLED and connected to the transistor.

The thin-film encapsulation layer TFE may be disposed on the circuit element layer DP-CL to cover the display element layer DP-OLED. The thin-film encapsulation layer TFE may protect the pixels from moisture, oxygen, and foreign substances of the outside. The thin-film encapsulation layer TFE may include inorganic layers and an organic layer. The organic layer may be disposed between the inorganic layers, encapsulated from the inorganic layers, and provide a flat surface. In an embodiment, the organic layer may be disposed on the inorganic layers or omitted, and is not limited to a particular embodiment.

FIG. 4A is a block diagram of the electronic device illustrated in FIG. 1A.

Referring to FIG. 4A, the electronic device DD may include a display panel DP, a timing controller T-C, a scan driver SDC, a data driver DDV, a light emission driver EDV, and a voltage generator VG.

The display panel DP may include a plurality of scan lines GIL1 to GILm, GCL1 to GCLm, GWL1 to GWLm, and GBL1 to GBLm, a plurality of light emission lines EML1 to EMLm, a plurality of data lines DL1 to DLn, and a plurality of pixels PX. Here, m and n are natural numbers.

The pixels PX may be electrically connected to the scan lines GIL1 to GILm, GCL1 to GCLm, GWL1 to GWLm, and GBL1 to GBLm, the light emission lines EML1 to EMLm, and the data lines DL1 to DLn. Each of the pixels PX may be electrically connected to four corresponding scan lines, one corresponding data line, and one corresponding light emission line.

The scan lines GIL1 to GILm, GCL1 to GCLm, GWL1 to GWLm, and GBL1 to GBLm may include a plurality of initialization scan lines GIL1 to GILm, a plurality of compensation scan lines GCL1 to GCLm, a plurality of write scan lines GWL1 to GWLm, and a plurality of bias scan lines GBL1 to GBLm.

Each of the pixels PX may be connected to corresponding one of the initialization scan lines GIL1 to GILm, corresponding one of the compensation scan lines GCL1 to GCLm, corresponding one of the write scan lines GWL1 to GWLm, and corresponding one of the bias scan lines GBL1 to GBLm.

The scan lines GIL1 to GILm, GCL1 to GCLm, GWL1 to GWLm, and GBL1 to GBLm may be connected to the scan driver SDC, extend in the first direction DR1, and may be arranged in the second direction DR2. The light emission lines EML1 to EMLm may be connected to the light emission driver EDV, extend in the first direction DR1, and may be arranged in the second direction DR2. The data lines DL1 to DLn may be connected to the data driver DDV, extend in the second direction DR2, and may be arranged in the first direction DR1.

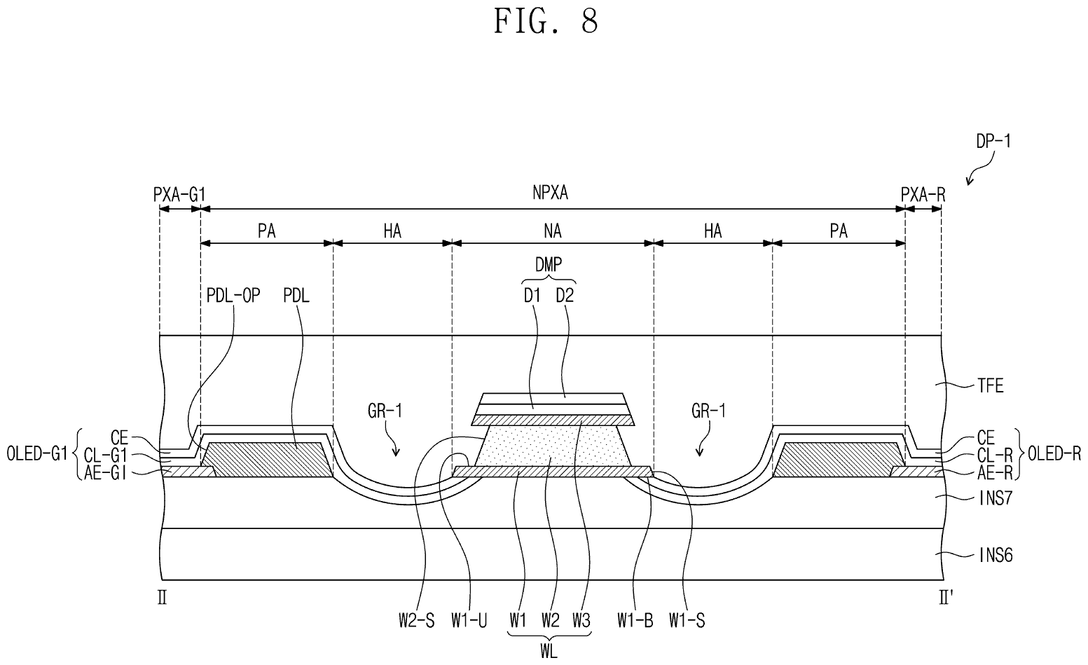

The scan driver SDC, the light emission driver EDV, and the data driver DDV may be substantially disposed on the display panel DP, and such a configuration will be illustrated in FIG. 8 below.

The timing controller T-C may receive an image signal RGB and a control signal CTRL. The timing controller T-C may generate an image data signal DAS obtained by converting data format of the image signal RGB to comply with specifications of interface with the data driver DDV. The timing controller T-C may output a scan control signal SCS, a data control signal DCS, and a light emission control signal ECS in response to the control signal CTRL.

The voltage generator VG may generate voltages that are desired for operation of the display panel DP. The voltage generator VG may generate a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the pixels PX.

The scan driver SDC may receive the scan control signal SCS from the timing controller T-C. The scan driver SDC may output scan signals to the scan lines GIL1 to GILm, GCL1 to GCLm, GWL1 to GWLm, and GBL1 to GBLm in response to the scan control signal SCS. The scan signals may be applied to the pixels PX through the scan lines GIL1 to GILm, GCL1 to GCLm, GWL1 to GWLm, and GBL1 to GBLm.

The data driver DDV may receive the data control signal DCS and the image data signal DAS from the timing controller T-C. The data driver DDV may convert the image data signal DAS into data signals and output the data signals. The data signals may be defined as analog voltages corresponding to a gray scale level of the image data signal DAS. The data signals may be applied to the pixels PX through the data lines DL1 to DLn.

The light emission driver EDV may receive the light emission control signal ECS from the timing controller T-C. The light emission driver EDV may output light emission signals to the light emission lines EML1 to EMLm in response to the light emission control signal ECS. The light emission signals may be applied to the pixels PX through the light emission lines EML1 to EMLm.

The pixels PX may be provided with data voltages in response to the scan signals. The pixels PX may display an image by emitting light having luminance corresponding to the data voltages in response to the light emission signals.

FIG. 4B is a diagram illustrating an equivalent circuit of one pixel among the pixels illustrated in FIG. 4A.

As one of the embodiments, FIG. 4B illustrates a pixel PXij connected to a j-th data line DLj, i-th scan lines GWLi, GCLi, GILi, and GBLi, and an i-th light emission line EMLi. Here, i and j are natural numbers equal to or less than m and n, respectively.

Referring to FIG. 4B, the pixel PXij may include a pixel circuit PC and a light-emitting element OLED connected to the pixel circuit PC. The pixel circuit PC may drive the light-emitting element OLED.

The pixel circuit PC may include a plurality of transistors T1 to T8 and a capacitor CST. The transistors T1 to T8 and the capacitor CST may control the amount of current flowing through the light-emitting element OLED. The light-emitting element OLED may generate light having predetermined luminance according to the amount of provided current.

An i-th write scan line GWLi may receive an i-th write scan signal GWi, and an i-th compensation scan line GCLi may receive an i-th compensation scan signal GCi. An i-th initialization scan line GILi may receive an i-th initialization scan signal GIi, and an i-th bias scan line GBLi may receive an i-th bias scan signal GBi. The i-th light emission line EMLi may receive an i-th light emission signal EMi.

The pixel PXij may be connected to the j-th data line DLj, the i-th write scan line GWLi, the i-th compensation scan line GCLi, the i-th initialization scan line GILi, the i-th bias scan line GBLi, the i-th light emission line EMLi, a first initialization line VIL1, a second initialization line VIL2, a bias line VBL, and first and second power lines PL1 and PL2.

The first initialization line VIL1 may receive a first initialization voltage VINT, and the second initialization line VIL2 may receive a second initialization voltage VAINT. The bias line VBL may receive a bias voltage VBIAS. The first power line PL1 may receive a first driving voltage ELVDD, and the second power line PL2 may receive a second driving voltage ELVSS.

The transistors T1 to T8 may each include a source electrode, a drain electrode, and a gate electrode. Hereinafter, in FIG. 4B, for convenience, any one of a source electrode and a drain electrode is defined as a first electrode, and a remaining (the other) one is defined as a second electrode. In addition, a gate electrode is defined as a control electrode.

The transistors T1 to T8 may include first to eighth transistors T1 to T8. The first, second, and fifth to eighth transistors T1, T2, and T5 to T8 may be p-type metal oxide semiconductor (“PMOS”) transistors. The third and fourth transistors T3 and T4 may be n-type metal oxide semiconductor (“NMOS”) transistors.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as an initialization transistor. The fifth transistor T5 and the sixth transistor T6 may be defined as a light emission control transistor. The eighth transistor T8 may be defined as a bias transistor.

The light-emitting element OLED may be defined as an organic light-emitting element. The light-emitting element OLED may include a first electrode AE and a second electrode CE. The first electrode AE may receive the first driving voltage ELVDD through the sixth, first and fifth transistors T6, T1, and T5. The first driving voltage ELVDD may be applied to the pixel circuit PC through the first power line PL1.

The second electrode CE may receive the second driving voltage ELVSS having a lower level than the first driving voltage ELVDD. The second driving voltage ELVSS may be applied to the pixel circuit PC through the second power line PL2.

The first transistor T1 may be disposed between the fifth transistor T5 and the sixth transistor T6 and connected to the fifth transistor T5 and the sixth transistor T6. The first transistor T1 may be connected to the first power line PL1 through the fifth transistor T5 and may be connected to the first electrode AE through the sixth transistor T6.

The first transistor T1 may include a first electrode connected to the first power line PL1 through the fifth transistor T5, a second electrode connected to the first electrode AE through the sixth transistor T6, and a control electrode connected to a first node N1.

The first electrode of the first transistor T1 may be connected to the fifth transistor T5, and the second electrode of the first transistor T1 may be connected to the sixth transistor T6. The first transistor T1 may control the amount of current flowing through the light-emitting element OLED according to a voltage, of the first node N1, applied to the control electrode of the first transistor T1.

The second transistor T2 may be disposed between the first transistor T1 and the j-th data line DLj and connected to the first transistor T1 and the j-th data line DLj. The second transistor T2 may include a first electrode connected to the j-th data line DLj, a second electrode connected to the first electrode of the first transistor T1, and a control electrode connected to the i-th write scan line GWLi.

The second transistor T2 may be turned on by the i-th write scan signal GWi applied through the i-th write scan line GWLi and may electrically connect the j-th data line DLj and the first electrode of the first transistor T1. The second transistor T2 may perform a switching operation of providing, to the first electrode of the first transistor T1, a data voltage VD (which corresponds to the data signal described above) applied through the j-th data line DLj.

The third transistor T3 may be connected to the second electrode of the first transistor T1 and the first node N1. The third transistor T3 may include a first electrode connected to the second electrode of the first transistor T1, a second electrode connected to the first node N1, and a control electrode connected to the i-th compensation scan line GCLi.

The third transistor T3 may be turned on by the i-th compensation scan signal GCi applied through the i-th compensation scan line GCLi and may electrically connect the second electrode of the first transistor T1 and the control electrode of the first transistor T1. When the third transistor T3 is turned on, the first transistor T1 and the third transistor T3 may be diode-connected.

The fourth transistor T4 may be connected to the first node N1. The fourth transistor T4 may include a first electrode connected to the first node N1, a second electrode connected to the first initialization line VIL1 and a control electrode connected to the i-th initialization scan line GILi. The fourth transistor T4 may be turned on by the i-th initialization scan signal GIi applied through the i-th initialization scan line GILi and may provide, to the first node N1, the first initialization voltage VINT applied through the first initialization line VIL1.

The fifth transistor T5 may include a first electrode connected to the first power line PL1, a second electrode connected to the first electrode of the first transistor T1 and a control electrode connected to the i-th light emission line EMLi.

The sixth transistor T6 may include a first electrode connected to the second electrode of the first transistor T1, a second electrode connected to the first electrode AE and a control electrode connected to the i-th light emission line EMLi.

The fifth transistor T5 and the sixth transistor T6 may be turned on by the i-th light emission signal EMi applied through the i-th light emission line EMLi. The first driving voltage ELVDD may be provided to the light-emitting element OLED by the fifth transistor T5 and the sixth transistor T6 which are turned on, and driving current may flow through the light-emitting element OLED. Thus, the light-emitting element OLED may emit light.

The seventh transistor T7 may include a first electrode connected to the first electrode AE, a second electrode connected to the second initialization line VIL2 and a control electrode connected to the i-th bias scan line GBLi. The seventh transistor T7 may be turned on by the i-th bias scan signal GBi applied through the i-th bias scan line GBLi and may provide, to the first electrode AE of the light-emitting element OLED, the second initialization voltage VAINT received through the second initialization line VIL2.

In an embodiment of the inventive concept, the second initialization voltage VAINT may have a different level from the first initialization voltage VINT but is not limited thereto and may have the same level as the first initialization voltage VINT.

The seventh transistor T7 may improve a black color expression capability of the pixel PXij. When the seventh transistor T7 is turned on, a parasitic capacitor (not shown) of the light-emitting element OLED may be discharged. Thus, when implementing black luminance, the light-emitting element OLED does not emit light due to leakage current of the first transistor T1, and thus a black color expression capability may be improved.

The capacitor CST may include a first electrode connected to the first power line PL1 and a second electrode connected to the first node N1. When the fifth transistor T5 and the sixth transistor T6 are turned on, the amount of current flowing through the first transistor T1 may be determined according to a voltage stored in the capacitor CST.

The eighth transistor T8 may include a first electrode connected to the bias line VBL, a second electrode connected to the first electrode of the first transistor T1 and a control electrode connected to the i-th bias scan line GBLi.

The eighth transistor T8 may be turned on by the i-th bias scan signal GBi and may provide, to the first electrode of the first transistor T1, the bias voltage VBIAS applied through the bias line VBL. However, transistors included in the pixel PXij are not limited thereto.

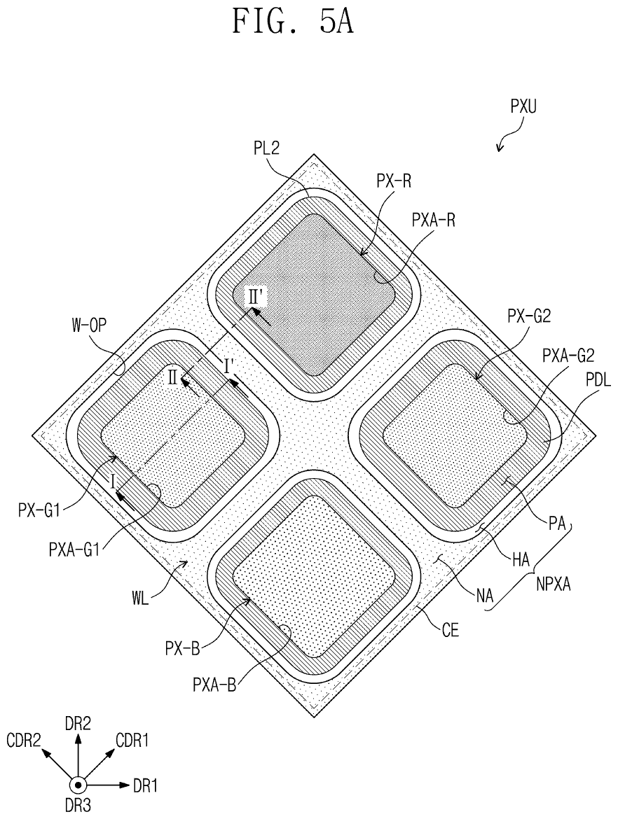

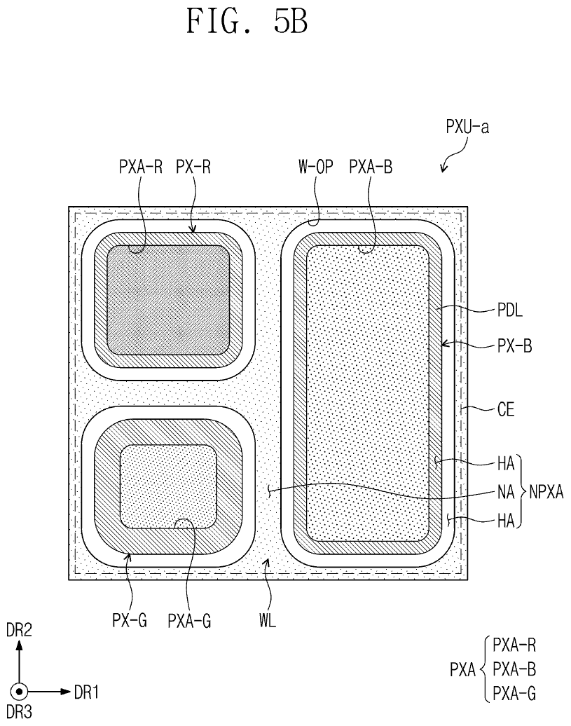

FIG. 5A is a plan view of an embodiment of a pixel unit according to the inventive concept. FIG. 5B is a plan view of an embodiment of a pixel according to the inventive concept.

Referring to FIG. 5A, in the illustrated embodiment, one pixel unit PXU may include the pixels described with reference to FIGS. 4A and 4B. The pixel unit PXU may be provided in plural so that plural pixel unit PXU may be arranged along first and second diagonal directions CDR1 and CDR2 in the display region DA described with reference to FIG. 1A.

The pixel unit PXU in an embodiment may include (1-1)-th to third pixels PX-G1, PX-G2, PX-R and PX-B. The (1-1)-th pixel PX-G1 may provide green light. Light which is generated in the (1-1)-th pix PX-G1 may be provided to the display region DA (refer to FIG. 1A) through a (1-1)-th light-emitting region PXA-G1. In the illustrated embodiment, the (1-1)-th light-emitting region PXA-G1 may have a rhombic shape.

The (1-2)-th pixel PX-G2 may provide green light like the (1-1)-th pixel PX-G1. Light which is generated in the (1-2)-th pixel PX-G2 may be provided to the display region DA (refer to FIG. 1A) through a (1-2)-th light-emitting region PXA-G2. The (1-2)-th light-emitting region PXA-G2 may be spaced apart from the (1-1)-th light-emitting region PXA-G1 along the first direction DR1. In the illustrated embodiment, the (1-2)-th light-emitting region PXA-G2 may have a rhombic shape.

The second pixel PX-R may provide red light. Light which is generated in the second pixel PX-R may be provided to the display region DA (refer to FIG. 1A) through a second light-emitting region PXA-R. The second light-emitting region PXA-R may be spaced apart from a third light-emitting region PXA-B along the second direction DR2. The second light-emitting region PXA-R may be spaced apart from the (1-1)-th light-emitting region PXA-G1 along the first diagonal direction CDR1 and may be spaced apart from the (1-2)-th light-emitting region PXA-G2 along the second diagonal direction CDR2. In the illustrated embodiment, the second light-emitting region PXA-R may have a rhombic shape.

The third pixel PX-B may provide blue light. Light which is generated in the third pixel PX-B may be provided to the display region DA (refer to FIG. 1A) through the third light-emitting region PXA-B. The third light-emitting region PXA-B may be spaced apart from the (1-2)-th light-emitting region PXA-G2 along the first diagonal direction CDR1 and may be spaced apart from the (1-1)-th light-emitting region PXA-G1 along the first diagonal direction CDR1. In the illustrated embodiment, the third light-emitting region PXA-B may have a rhombic shape.

In an embodiment, an area of the second light-emitting region PXA-R may be greater than areas of the (1-1)-th and (1-2)-th light-emitting regions PXA-G1 and PXA-G2 and smaller than an area of the third light-emitting region PXA-B.

A region between the (1-1)-th to third light-emitting regions PXA-G1, PXA-G2, PXA-R and PXA-B may be defined as a non-light-emitting region NPXA.

Pixel-defining patterns PDL may be disposed in the non-light-emitting region NPXA. The (1-1)-th to third light-emitting regions PXA-G1, PXA-G2, PXA-R and PXA-B may correspond to openings defined in the pixel-defining patterns PDL. The pixel-defining patterns PDL may each surround a corresponding light-emitting element. The pixel-defining patterns PDL may each have a closed-line shape. In an embodiment, widths of the pixel-defining patterns PDL surrounding light-emitting elements which provide light of different colors may be different from each other. However, the inventive concept is not limited thereto, and the widths of the pixel-defining patterns PDL may be the same as each other.

According to the inventive concept, a partition wall WL may be disposed between the pixel-defining patterns PDL. Partition wall openings W-OP overlapping the (1-1)-th to third light-emitting regions PXA-G1, PXA-G2, PXA-R and PXA-B may be defined in the partition wall WL. In the illustrated embodiment, each of the partition wall openings W-OP may have a rhombic shape. The partition wall WL may include a plurality of conductive layers. Since the plurality of conductive layers respectively have widths different from each other, the plurality of conductive layers may have an undercut shape in a cross-sectional view. Description thereof will be made later.

FIG. 5A illustrates a second electrode CE of a light-emitting element included in each of the pixels PX-G1, PX-G2, PX-R and PX-B in a dashed line. The second electrode CE included in the light-emitting elements is formed all over a light-emitting region PXA and the non-light-emitting region NPXA, but the second electrode CE may be disconnected by the partition wall WL in an undercut shape. However, since the partition wall WL includes conductive layers, the second electrodes CE disconnected by the partition wall WL may contact any one conductive layer included in the partition wall WL, and the second electrodes CE may be connected to each other through the conductive layer. Accordingly, the second electrodes CE may receive the same voltage. Description thereof will be made later.

According to the inventive concept, the non-light-emitting region NPXA may include pattern regions PA, recessed regions HA and a partition wall region NA disposed between the recessed regions HA. The pattern regions PA may be defined as a region in which the pixel-defining patterns PDL are disposed. The partition wall region NA may be defined as a region in which the partition wall WL is disposed. The recessed regions HA may be defined as a region between the pixel-defining patterns PDL and the partition wall WL. In a cross-sectional view, two recessed regions HA may be next (adjacent) to each other with one partition wall region NA therebetween.

Referring to FIG. 5B, in the illustrated embodiment, one pixel unit PXU-a may include the pixels described with reference to FIGS. 4A and 4B. The pixel unit PXU-a may be provided in plural so that plural pixel units PXU-a may be disposed along the first and second directions DR1 and DR2 in the display region DA described with reference to FIG. 1A.

The pixel unit PXU-a in an embodiment may include first to third pixels PX-R, PX-B and PX-G. The first pixel PX-R may provide red light. Light which is generated in the first pixel PX-R may be provided to the display region DA (refer to FIG. 1A) through a first light-emitting region PXA-R. In the illustrated embodiment, the first light-emitting region PXA-R may have a round-cornered quadrangular shape.

The second pixel PX-B may provide blue light. Light which is generated in the second pixel PX-B may be provided to the display region DA (refer to FIG. 1A) through a second light-emitting region PXA-B. The second light-emitting region PXA-B may be spaced apart from the first light-emitting region PXA-R along the first direction DR1. When viewed in the second direction DR2, the second light-emitting region PXA-B may overlap first and third light-emitting regions PXA-R and PXA-G. The second light-emitting region PXA-B may have a round-cornered quadrangular shape extending along the second direction DR2.

The third pixel PX-G may provide green light. Light which is generated in the third pixel PX-G may be provided to the display region DA (refer to FIG. 1A) through the third light-emitting region PXA-G. The third light-emitting region PXA-G may be spaced apart from the first light-emitting region PXA-R along the second direction DR2. The third light-emitting region PXA-G may have a round-cornered quadrangular shape.

In an embodiment, an area of the first light-emitting region PXA-R may be greater than an area of the third light-emitting region PXA-G and smaller than an area of the second light-emitting region PXA-B.

A region between the first to third light-emitting regions PXA-R, PXA-B and PXA-G may be defined as a non-light-emitting region NPXA.

Pixel-defining patterns PDL may be disposed in the non-light-emitting region NPXA. The first to third light-emitting regions PXA-R, PXA-B and PXA-G may correspond to an opening defined in the pixel-defining patterns PDL. The pixel-defining patterns PDL may each surround a corresponding light-emitting element. The pixel-defining patterns PDL may each have a closed-line shape.

According to the inventive concept, a partition wall WL may be disposed between the pixel-defining patterns PDL. Partition wall openings W-OP overlapping the first to third light-emitting regions PXA-R, PXA-B and PXA-G may be defined in the partition wall WL. In the illustrated embodiment, the partition wall openings W-OP may each have a quadrangular shape. The partition wall WL may include a plurality of conductive layers. Since the plurality of conductive layers respectively have widths different from each other, the plurality of conductive layers may have an undercut shape in a cross-sectional view. Description thereof will be made later.

FIG. 5B illustrates a second electrode CE included in a light-emitting element included in each of the first to third pixels PX-R, PX-B and PX-G in a dashed line. The second electrode CE included in the light-emitting elements is formed all over a light-emitting region PXA and the non-light-emitting region NPXA, but the second electrode CE may be disconnected by the partition wall WL in an undercut shape. However, since the partition wall WL includes conductive layers, the second electrodes CE disconnected by the partition wall WL may contact any one conductive layer included in the partition wall WL, and the second electrodes CE may be connected to each other through the conductive layer. Accordingly, the second electrodes CE may receive the same voltage. Description thereof will be made later.

According to the inventive concept, the non-light-emitting region NPXA may include pattern regions PA, recessed regions HA and a partition wall region NA disposed between the recessed regions HA. The pattern regions PA may be defined as a region in which the pixel-defining patterns PDL are disposed. The partition wall region NA may be defined as a region in which the partition wall WL is disposed. The recessed regions HA may be defined as a region between the pixel-defining patterns PDL and the partition wall WL.

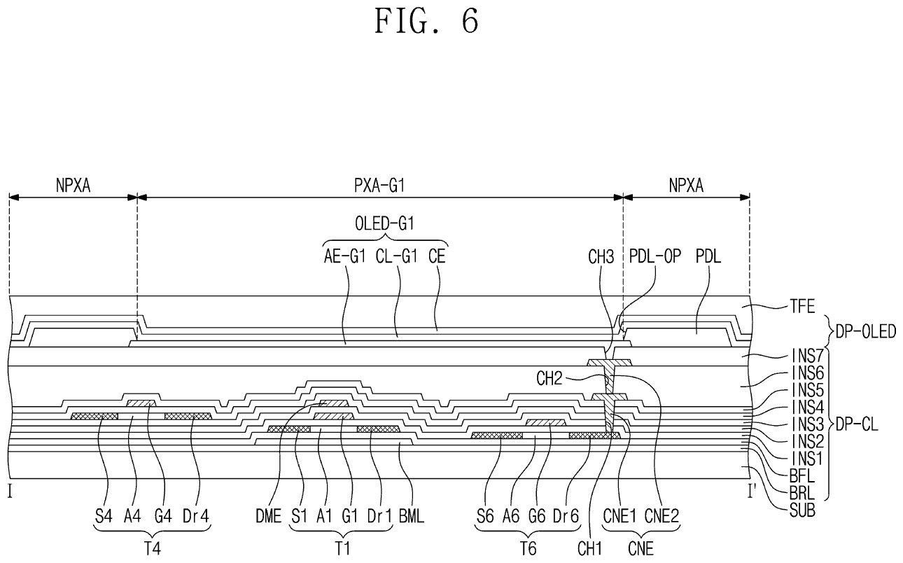

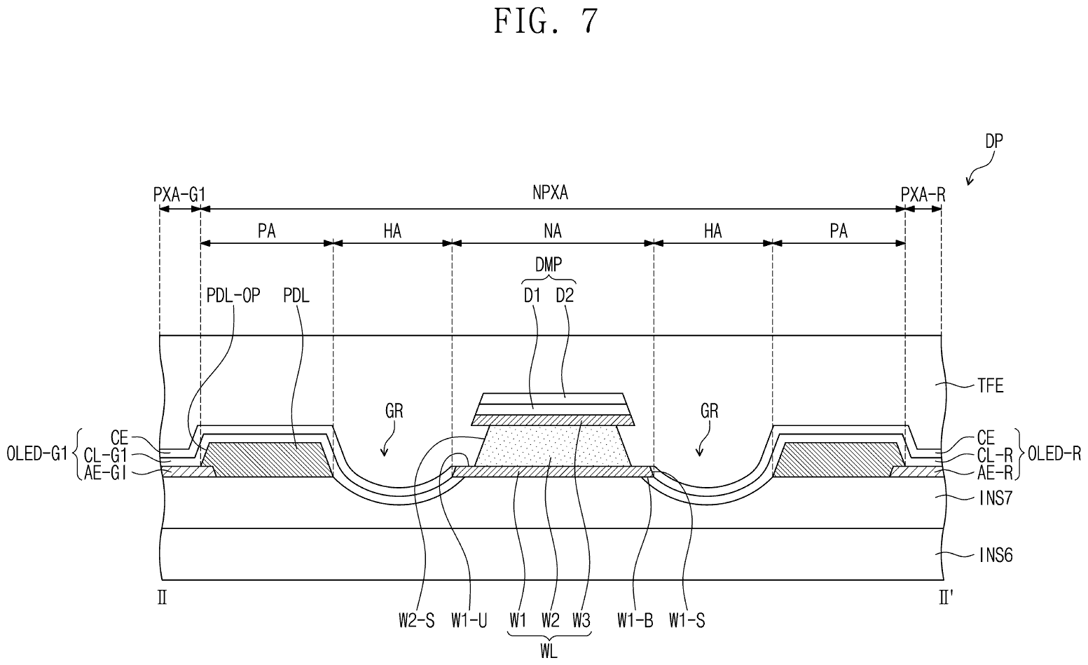

FIG. 6 is a cross-sectional view taken along I-I′ of FIG. 5A. FIG. 7 is a cross-sectional view taken along II-II′ of FIG. 5A.

FIG. 6 illustrates a cross-sectional view of the (1-1)-th pixel PX-G1 of FIG. 5A. Referring to FIG. 6, a light-emitting element OLED-G1 in an embodiment may include a first electrode AE-G1, a second electrode CE and a first common layer CL-G1. The first common layer CL-G1 may include a hole control layer, an electron control layer, an emission layer, or the like.

The second electrode CE may be disposed on the first electrode AE-G1, and the first common layer CL-G1 may be disposed between the first electrode AE-G1 and the second electrode CE. The light-emitting element OLED-G1 in an embodiment may further include a protective layer disposed on the second electrode CE. The protective layer may include an organic material and prevent components disposed below the protective layer from being damaged in a subsequent process. In an embodiment, the protective layer may be omitted.

First, fourth and sixth transistors T1, T4 and T6 and the light-emitting element OLED-G1 may be disposed on a substrate SUB. The display region DA (refer to FIG. 1A) may include a (1-1)-th light-emitting region PXA-G1 corresponding to the pixel PXij (refer to FIG. 4B) and a non-light-emitting region NPXA next (adjacent) to the (1-1)-th light-emitting region PXA-G1.

The substrate SUB may include glass or include a flexible plastic material such as polyimide. A circuit element layer DP-CL, a display element layer DP-OLED and a thin-film encapsulation layer TFE may be disposed on the substrate SUB. The circuit element layer DP-CL may be disposed on the substrate SUB. The circuit element layer DP-CL may include insulating layers and conductive patterns. The display element layer DP-OLED may include the light-emitting element OLED-G1 and pixel-defining patterns PDL.

A barrier layer BRL may be disposed on the substrate SUB. The barrier layer BRL may increase bonding force between a semiconductor pattern included in transistors and the substrate SUB. The barrier layer BRL may include an inorganic material.

A metal layer BML may be disposed on the barrier layer BRL. The metal layer BML may overlap the first transistor T1. In an embodiment, the metal layer BML may receive a constant voltage. When the constant voltage is applied to the metal layer BML, a value of a threshold voltage Vth of the first transistor T1 disposed on the metal layer BML may be maintained without being changed.

The metal layer BML may block light incident to the first transistor T1 from below the metal layer BML. The metal layer BML may include reflective metal. In an embodiment, the metal layer BML may be omitted.

A buffer layer BFL may be disposed on the barrier layer BRL and cover the metal layer BML. The buffer layer BFL may include an inorganic material.

A semiconductor layer S1, A1 and Dr1 of the first transistor T1 and a semiconductor layer S6, A6 and Dr6 of the sixth transistor T6 may be disposed on the buffer layer BFL. The semiconductor layers S1, A1, Dr1, S6, A6 and Dr6 may include polysilicon. However, the inventive concept is not limited thereto, and the semiconductor layers S1, A1, Dr1, S6, A6 and Dr6 may include amorphous silicon.

The semiconductor layers S1, A1, Dr1, S6, A6 and Dr6 may be doped with an N-type dopant or a P-type dopant. The semiconductor layers S1, A1, Dr1, S6, A6 and Dr6 may include a heavily doped region and a lightly doped region. The heavily doped region may have greater conductivity than the lightly doped region and may substantially serve as a source electrode and a drain electrode of the first and sixth transistors T1 and T6. The lightly doped region may substantially correspond to an active (or channel) of the first and sixth transistors T1 and T6.

A first source region S1, a first channel region A1 and a first drain region Dr1 of the first transistor T1 may be formed from the semiconductor layer S1, A1 and Dr1. A sixth source region S6, a sixth channel region A6 and a sixth drain region Dr6 of the sixth transistor T6 may be formed from the semiconductor layer S6, A6 and Dr6. The first channel region A1 may be disposed between the first source region S1 and the first drain region Dr1. The sixth channel region A6 may be disposed between the sixth source region S6 and the sixth drain region Dr6.

A first insulating layer INS1 may be disposed on the buffer layer BFL to cover the semiconductor layers S1, A1, Dr1, S6, A6 and Dr6. A first gate electrode G1 (or a control electrode) of the first transistor T1 and a sixth gate electrode G6 (or a control electrode) of the sixth transistor T6 may be disposed on the first insulating layer INS1. In a plan view, the first gate electrode G1 may overlap the first channel region A1, and the sixth gate electrode G6 may overlap the sixth channel region A6.

Although not illustrated, a structure of a source region, a channel region, a drain region and a gate electrode of each of the second, fifth and seventh transistors T2, T5 and T7 may be substantially the same as that of the first and sixth transistors T1 and T6.

A second insulating layer INS2 may be disposed on the first insulating layer INS1 to cover the first and sixth gate electrodes G1 and G6. A dummy electrode DME may be disposed on the second insulating layer INS2. The dummy electrode DME may be disposed on the first gate electrode G1 and, in a plan view, overlap the first gate electrode G1. The dummy electrode DME may form the capacitor described above with the first gate electrode G1.

A third insulating layer INS3 may be disposed on the second insulating layer INS2 to cover the dummy electrode DME. A semiconductor layer S4, A4 and Dr4 of the fourth transistor T4 may be disposed on the third insulating layer INS3. The semiconductor layer S4, A4 and Dr4 may include oxide semiconductor which includes or consists of metal oxide. The oxide semiconductor may include crystalline or amorphous oxide semiconductor.

The semiconductor layer S4, A4 and Dr4 may include a plurality of regions which are divided according to whether metal oxide is reduced or not. A region (hereinafter, a reduced region) in which metal oxide is reduced may have greater conductivity than a region (hereinafter, a non-reduced region) in which metal oxide is not reduced. The reduced region may substantially serve as a source electrode or a drain electrode of the fourth transistor T4. The non-reduced region may substantially correspond to an active (or channel) of the fourth transistor T4.

A fourth source region S4, a fourth channel region A4 and a fourth drain region Dr4 of the fourth transistor T4 may be formed from the semiconductor layer S4, A4 and Dr4. The fourth channel region A4 may be disposed between the fourth source region S4 and the fourth drain region Dr4.

A fourth insulating layer INS4 may be disposed on the third insulating layer INS3 to cover the semiconductor layer S4, A4 and Dr4. A fourth gate electrode G4 of the fourth transistor T4 may be disposed on the fourth insulating layer INS4. In a plan view, the fourth gate electrode G4 may overlap the fourth channel region A4.

A fifth insulating layer INS5 may be disposed on the fourth insulating layer INS4 to cover the fourth gate electrode G4. Although not illustrated, a structure of a source region, a channel region, a drain region and a gate electrode of the third transistor T3 may be substantially the same as that of the fourth transistor T4.

The barrier layer BRL, the buffer layer BFL, and the first to fifth insulating layers INS1 to INS5 may include an inorganic material. As one of the embodiments, the barrier layer BRL, the buffer layer BFL and the first to fifth insulating layers INS1 to INS5 may include any one of silicon oxide and silicon nitride, or one insulating layer may include multi-layered inorganic layers, and the inventive concept is not limited thereto. The multi-layered inorganic layers may have a structure in which layers respectively including silicon nitride and silicon oxide are alternately stacked.

A connection electrode CNE may be disposed between the sixth transistor T6 and the light-emitting element OLED-G1. The connection electrode CNE may electrically connect the sixth transistor T6 and the light-emitting element OLED-G1. The connection electrode CNE may include a first connection electrode CNE1 and a second connection electrode CNE2 disposed on the first connection electrode CNE1.

The first connection electrode CNE1 may be disposed on the fifth insulating layer INS5 and connected to the sixth drain region Dr6 through a first contact hole CH1 which is defined in the first to fifth insulating layers INS1 to INS5. A sixth insulating layer INS6 (“inter-insulating layer” of the claims) may be disposed on the fifth insulating layer INS5 to cover the first connection electrode CNE1.

The second connection electrode CNE2 may be disposed on the sixth insulating layer INS6. The second connection electrode CNE2 may be connected to the first connection electrode CNE1 through a second contact hole CH2 which is defined in the sixth insulating layer INS6.

In the illustrated embodiment, the second power line PL2 may be disposed on the sixth insulating layer INS6 and covered with a seventh insulating layer INS7 (“intervening insulating layer” of the claims).

The seventh insulating layer INS7 may be disposed on the sixth insulating layer INS6 to cover the second connection electrode CNE2. The sixth and seventh insulating layers INS6 and INS7 may include any one of an organic material and an inorganic material.

The pixel-defining patterns PDL may be disposed on the seventh insulating layer INS7. An opening PDL-OP which exposes at least a portion of the first electrode AE-G1 may be defined in the pixel-defining patterns PDL. The opening PDL-OP may correspond to the light-emitting region described above. In the illustrated embodiment, the pixel-defining patterns PDL may include an organic material. In addition, the pixel-defining patterns PDL may have a predetermined color and are not limited to a particular embodiment.

The first common layer CL-G1 and the second electrode CE included in the light-emitting element OLED-G1 may be disposed on the pixel-defining patterns PDL.

The thin-film encapsulation layer TFE may be disposed on the light-emitting element OLED-G1 and cover the light-emitting element OLED-G1. The thin-film encapsulation layer TFE may be disposed in an entirety of the region of the display region DA. The thin-film encapsulation layer TFE may include inorganic films and an organic film disposed between the inorganic films and is not limited to a particular embodiment.

In FIG. 7, components from the substrate SUB up to the fifth insulating layer INS5 described with reference to FIG. 6 are not illustrated.

A display panel DP may include light-emitting regions PXA-G1 and PXA-R and a non-light-emitting region NPXA. The non-light-emitting region NPXA may include pattern regions PA, recessed regions HA, and a partition wall region NA. The partition wall region NA may be disposed between the recessed regions HA.

A pixel-defining pattern PDL is disposed in each of the pattern regions PA. The recessed region HA may be defined as a region between the pixel-defining pattern PDL and a partition wall WL, and the partition wall region NA may be defined as a region in which the partition wall WL is disposed.

The pixel-defining patterns PDL may be disposed on a seventh insulating layer INS7 (“intervening insulating layer” of the claims). A sixth insulating layer INS6 (“inter-insulating layer” of the claims) may be disposed below the seventh insulating layer INS7.

According to the inventive concept, the partition wall WL may be disposed between pixel-defining patterns PDL next (adjacent) to each other. The partition wall WL may include first to third layers W1, W2 and W3 each including a conductive material. The first layer W1 may contact the seventh insulating layer INS7. The second layer W2 may be disposed on the first layer W1, and the third layer W3 may be disposed on the second layer W2.

In the illustrated embodiment, the first layer W1 and the third layer W3 may include aluminum, and the second layer W2 may include titanium.

In a cross-sectional view, each of a width of the first layer W1 and a width of the third layer W3 may be greater than a width of the second layer W2. Thus, a portion of the first layer W1 and the third layer W3 may protrude from the second layer W2 to have an undercut structure. An undercut shape of the partition wall WL may be formed due to difference in etch rate with respect to an etchant between the first layer W1 and third layer W3 and the second layer W2. Each of a thickness of the first layer W1 and a thickness of the third layer W3 may be smaller than a thickness of the second layer W2.

According to the inventive concept, the second layer W2 may include aluminum, and thus a side surface W2-S of the second layer W2 may be oxidized and may not have conductivity.

According to the inventive concept, a groove GR may be defined in the seventh insulating layer INS7 overlapping the recessed region HA. The groove GR may be defined by recessing or removing at least a portion of the seventh insulating layer INS7 in a direction from an upper surface to a lower surface of the seventh insulating layer INS7. The groove GR may surround a corresponding pixel-defining pattern PDL. The groove GR may be surrounded by the partition wall WL. Thus, the groove GR may be formed between the pixel-defining pattern PDL and the partition wall WL. In the illustrated embodiment, the groove GR may have a concave shape.

In the illustrated embodiment, a portion (hereinafter, “the portion”) of a lower surface W1-B of the first layer W1 may be exposed from the seventh insulating layer INS7 by the groove GR. A common layer CL-G1 or CL-R and a second electrode CE included in each of a (1-1)-th light-emitting element OLED-G1 and a second light-emitting element OLED-R may extend from the light-emitting region PXA-G1 or PXA-R to the non-light-emitting region NPXA and may contact a portion of the partition wall WL.

The common layers CL-G1 and CL-R and the second electrode CE may be disposed on the pixel-defining pattern PDL in the pattern region PA, and the common layers CL-G1 and CL-R and the second electrode CE may be disposed in the groove GR in the recessed region HA.

In the illustrated embodiment, an end of each of the common layers CL-G1 and CL-R disposed in the groove GR may contact the portion of the lower surface W1-B of the first layer W1. The common layers CL-G1 and CL-R may be spaced apart from a side surface W1-S and an upper surface W1-U of the first layer W1 disposed at a lowermost portion of the partition wall WL.

In the illustrated embodiment, an end of the second electrode CE may contact the side surface W1-S of the first layer W1. Unlike the inventive concept, in a case in which the common layers CL-G1 and CL-R cover the first layer W1 and the second electrode CE contacts the second layer W2, the side surface W2-S of the second layer W2 is oxidized and does not have conductivity, and thus the second electrodes CE disconnected by the partition wall WL may not be connected to each other through the partition wall WL.

In the illustrated embodiment, the second electrodes CE physically disconnected due to formation of an undercut of the partition wall WL may be easily connected by forming the groove GR in the recessed region HA and bringing the second electrode CE into contact with the side surface W1-S of the first layer W1 by a shape of the groove GR.

In the illustrated embodiment, a dummy pattern DMP disposed on the partition wall WL may be further included. The dummy pattern DMP may include a first dummy pattern D1 disposed on the third layer W3 and a second dummy pattern D2 disposed on the first dummy pattern D1. The first dummy pattern D1 may include the same material as that of the common layers CL-G1 and CL-R, and the second dummy pattern D2 may include the same material as that of the second electrode CE.

The first and second dummy patterns D1 and D2 may be formed through disconnection of the common layers CL-G1 and CL-R and the second electrode CE due to the partition wall WL in a process of forming the common layers CL-G1 and CL-R and the second electrode CE all over the light-emitting regions PXA-G1 and PXA-R and the non-light-emitting region NPXA.

According to the inventive concept, in the display region DA (refer to FIG. 1A), the second electrodes CE may contact the side surface W1-S of the first layer W1 through the groove GR and may be prevented from being in contact with the side surface W2-S of the oxidized second layer W2. Accordingly, a voltage drop phenomenon may be prevented by easily connecting the second electrodes CE disconnected by the partition wall WL, and a constant voltage may be provided to pixels.

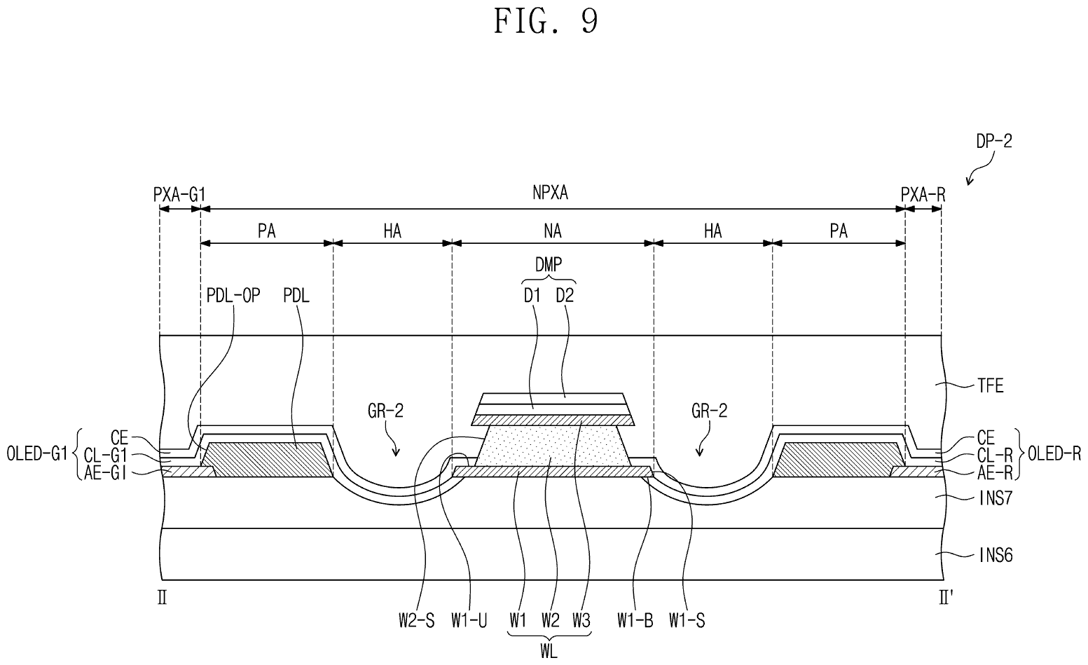

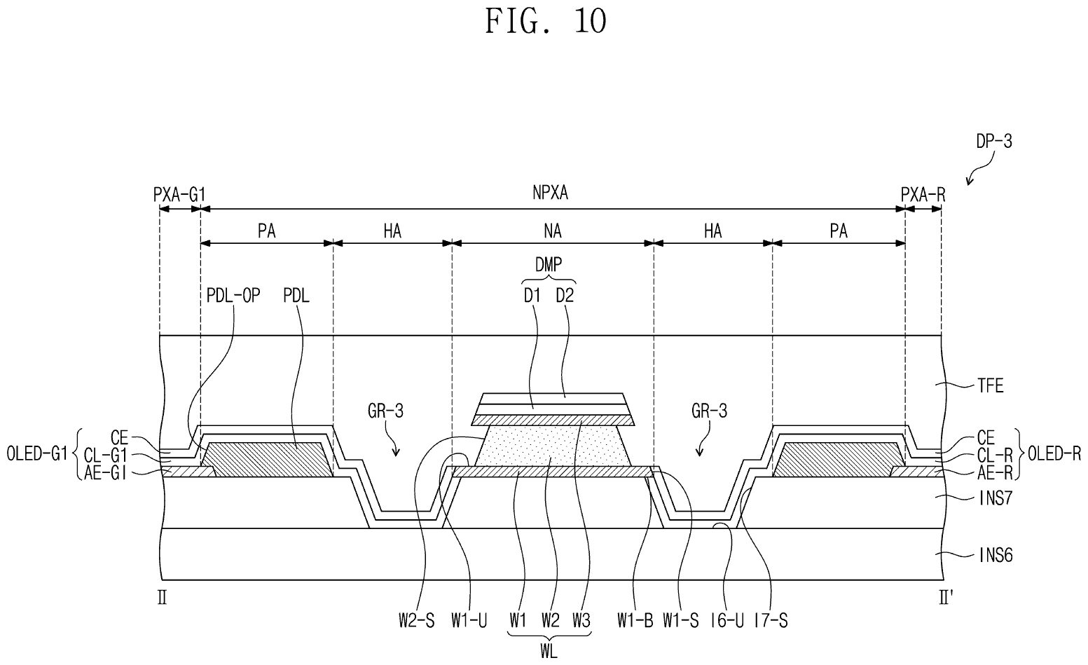

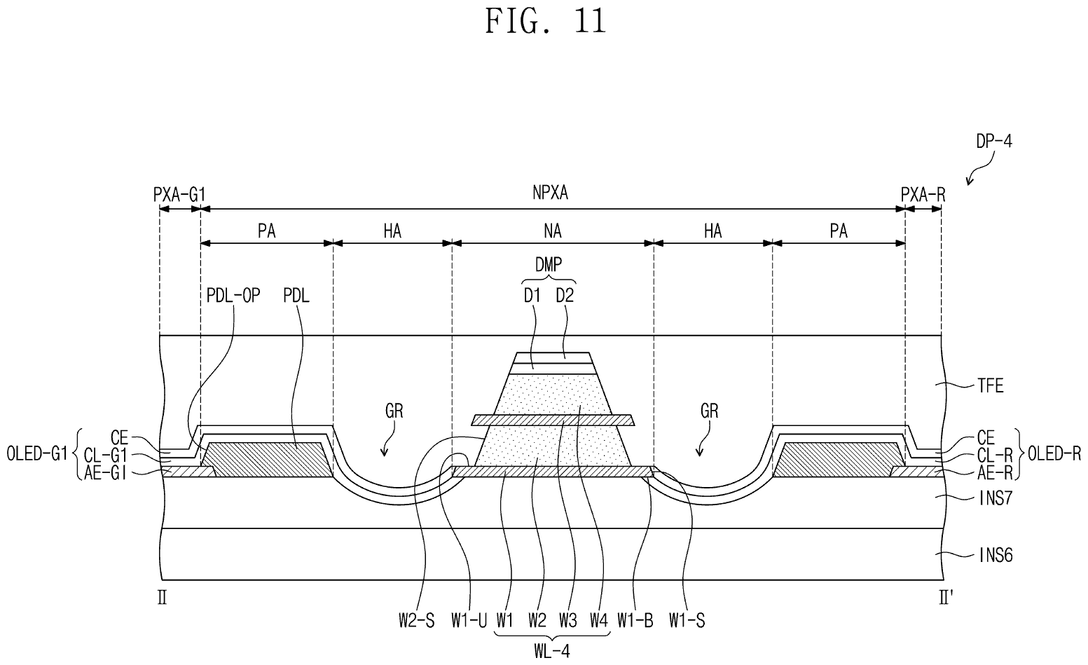

FIG. 8 is a cross-sectional view of an embodiment of a display panel according to the inventive concept. FIG. 9 is a cross-sectional view of an embodiment of a display panel according to the inventive concept. FIG. 10 is a cross-sectional view of an embodiment of a display panel according to the inventive concept. FIG. 11 is a cross-sectional view of an embodiment of a display panel according to the inventive concept.

FIGS. 8 to 11 are embodiments of a display panel with respect to the same region as that of FIG. 7. In FIGS. 8 to 11, components from the substrate SUB up to the fifth insulating layer INS5 described with reference to FIG. 6 are not illustrated. Components that are the same as/similar to those of FIG. 7 will be denoted as the same/similar reference numerals or symbols, and duplicate description will not be provided.

Referring to FIG. 8, a display panel DP-1 in an embodiment may include pixel-defining patterns PDL disposed in pattern regions PA and a partition wall WL disposed in a partition wall region NA.

The partition wall WL may be disposed between pixel-defining patterns PDL next (adjacent) to each other. The partition wall WL may include first to third layers W1, W2 and W3 each including a conductive material. The first layer W1 may contact a seventh insulating layer INS7. The second layer W2 may be disposed on the first layer W1, and the third layer W3 may be disposed on the second layer W2. A dummy pattern DMP may be disposed on the partition wall WL.

According to the inventive concept, a groove GR-1 may be defined in the seventh insulating layer INS7 overlapping a recessed region HA. The groove GR-1 may be defined by recessing or removing at least a portion of the seventh insulating layer INS7 in a direction from an upper surface to a lower surface of the seventh insulating layer INS7. The groove GR-1 may surround a corresponding pixel-defining pattern PDL. The groove GR-1 may be surrounded by the partition wall WL. Thus, the groove GR-1 may be formed between the pixel-defining pattern PDL and the partition wall WL. In the illustrated embodiment, the groove GR-1 may have a concave shape.

In the illustrated embodiment, a portion (hereinafter, “the portion”) of a lower surface W1-B of the first layer W1 may be exposed from the seventh insulating layer INS7 by the groove GR-3. A common layer CL-G1 or CL-R and a second electrode CE included in each of a (1-1)-th light-emitting element OLED-G1 and a second light-emitting element OLED-R may extend from a light-emitting region PXA-G1 or PXA-R to a non-light-emitting region NPXA and may contact a portion of the partition wall WL.

The common layers CL-G1 and CL-R and the second electrode CE may be disposed on the pixel-defining pattern PDL in the pattern region PA, and the common layers CL-G1 and CL-R and the second electrode CE may be disposed in the groove GR-1 in the recessed region HA.

In the illustrated embodiment, an end of each of the common layers CL-G1 and CL-R disposed in the groove GR-1 may contact the portion of the lower surface W1-B of the first layer W1. The common layers CL-G1 and CL-R may be spaced apart from a side surface W1-S and an upper surface W1-U of the first layer W1 disposed at a lowermost portion of the partition wall WL.

In the illustrated embodiment, an end of the second electrode CE may contact the portion of the lower surface W1-B of the first layer W1. That is, the end of each of the common layers CL-G1 and CL-R and the second electrode CE may contact the lower surface W1-B of the first layer W1.

In the illustrated embodiment, the second electrodes CE physically disconnected due to formation of an undercut of the partition wall WL may be easily connected by forming the groove GR-1 in the recessed region HA and bringing the second electrode CE into contact with the lower surface W1-B of the first layer W1 by a shape of the groove GR-1.

Referring to FIG. 9, a display panel DP-2 in an embodiment may include pixel-defining patterns PDL disposed in pattern regions PA and a partition wall WL disposed in a partition wall region NA.

The partition wall WL may be disposed between pixel-defining patterns PDL next (adjacent) to each other. The partition wall WL may include first to third layers W1, W2 and W3 each including a conductive material. The first layer W1 may contact a seventh insulating layer INS7. The second layer W2 may be disposed on the first layer W1, and the third layer W3 may be disposed on the second layer W2. A dummy pattern DMP may be disposed on the partition wall WL.

According to the inventive concept, a groove GR-2 may be defined in the seventh insulating layer INS7 overlapping a recessed region HA. The groove GR-2 may be defined by recessing or removing at least a portion of the seventh insulating layer INS7 in a direction from an upper surface to a lower surface of the seventh insulating layer INS7. The groove GR-2 may surround a corresponding pixel-defining pattern PDL. The groove GR-2 may be surrounded by the partition wall WL. Thus, the groove GR-2 may be formed between the pixel-defining pattern PDL and the partition wall WL. In the illustrated embodiment, the groove GR-2 may have a concave shape.

In the illustrated embodiment, a portion (hereinafter, “the portion”) of a lower surface W1-B of the first layer W1 may be exposed from the seventh insulating layer INS7 by the groove GR-2. A common layer CL-G1 or CL-R and a second electrode CE included in each of a (1-1)-th light-emitting element OLED-G1 and a second light-emitting element OLED-R may extend from a light-emitting region PXA-G1 or PXA-R to a non-light-emitting region NPXA and may contact a portion of the partition wall WL.

The common layers CL-G1 and CL-R and the second electrode CE may be disposed on the pixel-defining pattern PDL in the pattern region PA, and the common layers CL-G1 and CL-R and the second electrode CE may be disposed in the groove GR-2 in a recessed region HA.

In the illustrated embodiment, an end of each of the common layers CL-G1 and CL-R disposed in the groove GR-2 may contact the portion of the lower surface W1-B of the first layer W1. The common layers CL-G1 and CL-R may be spaced apart from a side surface W1-S and an upper surface W1-U of the first layer W1 disposed at a lowermost portion of the partition wall WL.

In the illustrated embodiment, the second electrode CE may contact the side surface W1-S and the upper surface W1-U of the first layer W1. In an embodiment, the second electrode CE may expose a portion of the upper surface W1-U of the first layer W1, or may completely cover the upper surface W1-U of the first layer W1 and contact a portion of a side surface W2-S of the second layer W2, and is not limited to a particular embodiment.

In the illustrated embodiment, the second electrodes CE physically disconnected due to formation of an undercut of the partition wall WL may be easily connected by forming the groove GR-2 in the recessed region HA and bringing the second electrode CE into contact with the side surface W1-S and the upper surface W1-U of the first layer W1 by a shape of the groove GR-2.

Referring to FIG. 10, a display panel DP-3 in an embodiment may include pixel-defining patterns PDL disposed in pattern regions PA and a partition wall WL disposed in a partition wall region NA.

The partition wall WL may be disposed between pixel-defining patterns PDL next (adjacent) to each other. The partition wall WL may include first to third layers W1, W2 and W3 each including a conductive material. The first layer W1 may contact a seventh insulating layer INS7. The second layer W2 may be disposed on the first layer W1, and the third layer W3 may be disposed on the second layer W2. A dummy pattern DMP may be disposed on the partition wall WL.

According to the inventive concept, a groove GR-3 may be defined in the seventh insulating layer INS7 overlapping a recessed region HA. The groove GR-3 may be defined by penetrating the seventh insulating layer INS7 from an upper surface of the seventh insulating layer INS7 to a lower surface of the seventh insulating layer INS7. In the illustrated embodiment, the groove GR-3 may expose a portion of an upper surface I6-U of a sixth insulating layer INS6. The groove GR-3 may be defined from a side surface I7-S of the seventh insulating layer INS7.

In the illustrated embodiment, a portion (hereinafter, “the portion”) of a lower surface W1-B of the first layer W1 may be exposed from the seventh insulating layer INS7 by the groove GR-3. A common layer CL-G1 or CL-R and a second electrode CE included in each of a (1-1)-th light-emitting element OLED-G1 and a second light-emitting element OLED-R may extend from a light-emitting region PXA-G1 or PXA-R to a non-light-emitting region NPXA and may contact a portion of the partition wall WL.

The common layers CL-G1 and CL-R and the second electrode CE may be disposed on the pixel-defining pattern PDL in the pattern region PA, and the common layers CL-G1 and CL-R and the second electrode CE may be disposed in the groove GR-3 in the recessed region HA.

In the illustrated embodiment, an end of each of the common layers CL-G1 and CL-R disposed in the groove GR-1 may contact the portion of the lower surface W1-B of the first layer W1. The common layers CL-G1 and CL-R may be spaced apart from a side surface W1-S and an upper surface W1-U of the first layer W1 disposed at a lowermost portion of the partition wall WL.

In the illustrated embodiment, an end of the second electrode CE may contact the side surface W1-S of the first layer W1. In an embodiment, the second electrode CE may contact at least a portion of the upper surface W1-U of the first layer W1, or may completely cover the upper surface W1-U of the first layer W1 and contact a portion of a side surface W2-S of the second layer W2, and is not limited to a particular embodiment.

In the illustrated embodiment, the second electrodes CE physically disconnected due to formation of an undercut of the partition wall WL may be easily connected by forming the groove GR-3 in the recessed region HA and bringing the second electrode CE into contact with the side surface W1-S of the first layer W1 by a shape of the groove GR-3.

FIG. 11 will be described mainly focusing on a difference from FIG. 7. Referring to FIG. 11, a display panel DP-4 in an embodiment may include a partition wall WL-4 disposed in a partition wall region NA of a non-light-emitting region NPXA. The partition wall WL-4 may surround pixel-defining patterns PDL. A recessed region HA may be defined between the pixel-defining patterns PDL and the partition wall WL-4.

The partition wall WL-4 may include first to fourth layers W1, W2, W3 and W4 each including a conductive material. The first layer W1 may contact a seventh insulating layer INS7. The second layer W2 may be disposed on the first layer W1, the third layer W3 may be disposed on the second layer W2, and the fourth layer W4 may be disposed on the third layer W3. A dummy pattern DMP may be disposed on the partition wall WL-4.

In the illustrated embodiment, the first layer W1 and the third layer W3 may include the same material, and the second layer W2 and the fourth layer W4 may include the same material as each other. In an embodiment, the first layer W1 and the third layer W3 may include any one of titanium and molybdenum-titanium alloy, for example. The second layer W2 and the fourth layer W4 may include any one of aluminum and copper.

In a cross-sectional view, each of a width of the first layer W1 and a width of the third layer W3 may be greater than each of a width of the second layer W2 and a width of the fourth layer W4. Thus, a portion of the first layer W1 and the third layer W3 may protrude from the second layer W2 to have an undercut structure. An undercut shape of the partition wall WL-4 may be formed due to difference in etch rate with respect to an etchant between the first layer W1 and third layer W3 and the second layer W2 and fourth layer W4. Each of a thickness of the first layer W1 and a thickness of the third layer W3 may be smaller than each of a thickness of the second layer W2 and a thickness of the fourth layer W4. In an embodiment, a side surface W2-S of the second layer W2 may be oxidized and may not have conductivity.

A second electrode CE in the illustrated embodiment may contact a side surface W1-S of the first layer W1. In an embodiment, the second electrode CE may expose a portion of an upper surface W1-U of the first layer W1, or may completely cover the upper surface W1-U of the first layer W1 and contact a portion of the side surface W2-S of the second layer W2, and is not limited to a particular embodiment.

According to the inventive concept, in a display region, through a groove, electrodes included in a light-emitting element may contact a side surface of a lower layer included in a partition wall and may be prevented from being in contact with a side surface of an oxidized intermediate layer. Accordingly, a voltage drop phenomenon may be prevented by easily connecting second electrodes disconnected by the partition wall, and a constant voltage may be provided to pixels.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. An electronic device comprising:
a substrate including:
a display region including light-emitting regions; and
a non-light-emitting region disposed between the light-emitting regions;
an intervening insulating layer disposed on the substrate;
a pixel unit disposed on the substrate and including:
light-emitting elements each including:
a first electrode and a second electrode overlapping a light-emitting region of the light-emitting regions and disposed on the intervening insulating layer; and
a common layer disposed between the first electrode and the second electrode;
pixel-defining patterns which are disposed on the intervening insulating layer; and
a partition wall overlapping the non-light-emitting region and disposed between the pixel-defining patterns next to each other on the intervening insulating layer, the partition wall including:
a first layer disposed on the intervening insulating layer;
a second layer disposed on the first layer; and
a third layer disposed on the second layer,
wherein an opening which corresponds to the light-emitting region and exposes at least a portion of the first electrode is defined in each of the pixel-defining patterns,
a groove, in which at least a portion of the intervening insulating layer is recessed in a direction from an upper surface to a lower surface of the intervening insulating layer, is defined in the intervening insulating layer in a recessed region which is defined between one of the pixel-defining patterns and the partition wall, and
the common layer and the second electrode extend from the light-emitting region to the recessed region and contact the first layer.

2. The electronic device of claim 1, wherein the groove exposes a portion of a lower surface of the first layer facing the intervening insulating layer.

3. The electronic device of claim 2, wherein the common layer contacts the portion of the lower surface.

4. The electronic device of claim 3, wherein the second electrode contacts a side surface of the first layer.

5. The electronic device of claim 3, wherein the second electrode contacts the portion of the lower surface and exposes a side surface of the first layer.

6. The electronic device of claim 3, wherein the second electrode contacts the portion of the lower surface, a side surface of the first layer, and a portion, of an upper surface of the first layer, exposed from the second layer.

7. The electronic device of claim 4, wherein in a cross-sectional view, the groove has a concave shape.

8. The electronic device of claim 4, further comprising an inter-insulating layer disposed below the intervening insulating layer,
wherein the groove penetrates the intervening insulating layer from the upper surface to the lower surface of the intervening insulating layer and exposes a portion of an upper surface of the inter-insulating layer.

9. The electronic device of claim 8, wherein the common layer contacts a side surface, defining the groove, of the intervening insulating layer, the portion of the upper surface of the inter-insulating layer, and the portion of the lower surface of the first layer.

10. The electronic device of claim 8, comprising:
transistors disposed on the substrate;
a first connection electrode disposed on the inter-insulating layer and connected to the transistors; and
a second connection electrode disposed on the intervening insulating layer and connected to the first connection electrode through a first contact hole defined in the inter-insulating layer,
wherein the first electrode is connected to the second connection electrode through a second contact hole defined in the intervening insulating layer.

11. The electronic device of claim 1, wherein the first layer and the third layer comprise titanium, and
the second layer comprises aluminum.

12. The electronic device of claim 11, wherein in a cross-sectional view, each of a width of the first layer and a width of the third layer is greater than a width of the second layer, and
each of a thickness of the first layer and a thickness of the third layer is smaller than a thickness of the second layer.

13. The electronic device of claim 12, further comprising a first dummy pattern disposed on the third layer and a second dummy pattern disposed on the first dummy pattern,
wherein the first dummy pattern includes a material identical to a material of the common layer, and
the second dummy pattern includes a material identical to a material of the second electrode.

14. The electronic device of claim 1, further comprising a fourth layer disposed on the third layer and including a metal different from a metal of the first layer and the third layer.

15. The electronic device of claim 14, wherein the first layer and the third layer comprise any one of titanium and molybdenum-titanium alloy, and
the second layer and the fourth layer comprise any one of aluminum and copper.

16. The electronic device of claim 1, wherein a side surface of the second layer is oxidized and does not have conductivity.

17. The electronic device of claim 1, wherein second electrodes disconnected with the partition wall therebetween are connected through the partition wall.

18. The electronic device of claim 1, wherein the intervening insulating layer comprises any one of an inorganic material and an organic material.

19. The electronic device of claim 1, further comprising an encapsulation layer covering the light-emitting elements.

20. The electronic device of claim 1, wherein the pixel unit is provided in plural in the display region in a manner in which each of pixel units comprises a (1-1)-th pixel which provides first color light, a (1-2)-th pixel which provides the first color light and is spaced apart from the (1-1)-th pixel along a first direction, a second pixel which provides second color light different from the first color light and is spaced apart from the (1-1)-th pixel in a first diagonal direction, and a third pixel which provides third color light different from the first color light and the second color light, is spaced apart from the second pixel along a second direction crossing the first direction, and is spaced apart from the (1-2)-th pixel along a second diagonal direction crossing the first diagonal direction.
